(19) United States
(12) Patent Application Publication
(10) Pub. No.: US 2026/0107440 A1
(43) Pub. Date: Apr. 16, 2026

(54) SEMICONDUCTOR DEVICE

(71) Applicant: Samsung Electronics Co., Ltd., Suwon-si (KR)

(72) Inventor: Hwayeong LEE, Suwon si (KR)

(21) Appl. No.: 19/214,340

(22) Filed: May 21, 2025

(30) Foreign Application Priority Data
Oct. 11, 2024 (KR) 10-2024-0138890

(51) Int. Cl. H10B 12/00

(52) U.S. Cl. CPC H10B 12/315; H10B 12/05

(57) ABSTRACT

A semiconductor device may include a bit line extending lengthwise in a first direction, a lower intervening structure on the bit line, a channel layer in contact with the lower intervening structure and spaced apart from the bit line, a word line extending lengthwise in a second direction crossing the first direction, and a gate insulating layer between the channel layer and the word line. The lower intervening structure may include amorphous silicon.

### CROSS-REFERENCE TO RELATED APPLICATIONS

This U.S. non-provisional patent application claims priority under 35 U.S.C. § 119 to Korean Patent Application No. 10-2024-0138890, filed on Oct. 11, 2024, in the Korean Intellectual Property Office, the entire contents of which are hereby incorporated by reference.

### BACKGROUND OF THE INVENTION

The present disclosure relates to a semiconductor device, and in particular, to a semiconductor device including an intervening structure.

As a semiconductor device is scaled down, it is necessary to develop a fabrication technology capable of increasing an integration density, an operation speed, and a production yield of a semiconductor device. Thus, semiconductor devices with vertical channel transistors have been suggested to increase an integration density of a semiconductor device and improve the resistance characteristics and current driving ability of the transistor.

### SUMMARY

An embodiment of the inventive concept provides a semiconductor device with improved electric characteristics and an increased integration density.

According to an embodiment of the inventive concept, a semiconductor device may include a bit line extending lengthwise in a first direction, a lower intervening structure on the bit line, a channel layer in contact with the lower intervening structure and spaced apart from the bit line, a word line extending lengthwise in a second direction crossing the first direction, and a gate insulating layer between the channel layer and the word line. The lower intervening structure may include amorphous silicon.

According to an embodiment of the inventive concept, a semiconductor device may include a bit line extending lengthwise in a first direction, a lower intervening structure on the bit line, a channel layer in contact with the lower intervening structure, a word line extending lengthwise in a second direction crossing the first direction, and a gate insulating layer between the channel layer and the word line. The lower intervening structure may include amorphous silicon, and the channel layer may include an oxide material.

According to an embodiment of the inventive concept, a semiconductor device may include a bit line extending lengthwise in a first direction, a lower intervening structure on the bit line, a bit line insulating layer in contact with a side surface of the lower intervening structure and a side surface of the bit line, a channel layer in contact with the lower intervening structure and spaced apart from the bit line, a word line spaced apart from the channel layer in the first direction and extending lengthwise in a second direction crossing the first direction, a gate insulating layer interposed between the channel layer and the word line, a gate capping layer on the word line, a landing pad on the channel layer, and a data storage pattern connected to the landing pad. The lower intervening structure may include amorphous silicon, and the channel layer may include an oxide material.

### BRIEF DESCRIPTION OF THE DRAWINGS

FIG. 1A is a block diagram illustrating a semiconductor device according to an example embodiment of the inventive concept.

FIGS. 1B and 1C are perspective views schematically illustrating a semiconductor device according to an example embodiment of the inventive concept.

FIG. 2 is a plan view illustrating a semiconductor device according to an example embodiment of the inventive concept.

FIG. 3 is a sectional view taken along a line A-A′ of FIG. 2.

FIG. 4 is a sectional view taken along a line B-B′ of FIG. 2.

FIG. 5 is a sectional view, which is taken along a line A-A′ of FIG. 2 to illustrate a semiconductor device according to an example embodiment of the inventive concept.

FIG. 6 is a sectional view, which is taken along a line B-B′ of FIG. 2 to illustrate a semiconductor device according to an example embodiment of the inventive concept.

FIG. 7 is a sectional view, which is taken along the line A-A′ of FIG. 2 to illustrate a semiconductor device according to an example embodiment of the inventive concept.

FIG. 8 is a sectional view, which is taken along the line B-B′ of FIG. 2 to illustrate a semiconductor device according to an example embodiment of the inventive concept.

FIGS. 9A, 10A, 11A, 12A, 13A, 14A, and 15A are plan views illustrating a method of fabricating a semiconductor device according to an example embodiment of the inventive concept.

FIGS. 9B, 10B, 11B, 12B, 13B, 14B, and 15B are sectional views, which are taken along the line A-A′ of FIG. 2 to illustrate a method of fabricating a semiconductor device, according to an example embodiment of the inventive concept.

FIGS. 9C, 10C, 11C, 12C, 13C, 14C, and 15C are sectional views, which are taken along the line B-B′ of FIG. 2 to illustrate a method of fabricating a semiconductor device, according to an example embodiment of the inventive concept.

FIGS. 16A, 17A, 18A, 19A, 20A, 21A, and 22A are plan views illustrating a method of fabricating a semiconductor device, according to an example embodiment of the inventive concept.

FIGS. 16B, 17B, 18B, 19B, 20B, 21B, and 22B are sectional views, which are taken along the line A-A′ of FIG. 2 to illustrate a method of fabricating a semiconductor device, according to an example embodiment of the inventive concept.

FIGS. 16C, 17C, 18C, 19C, 20C, 21C, and 22C are sectional views, which are taken along the line B-B′ of FIG. 2 to illustrate a method of fabricating a semiconductor device, according to an example embodiment of the inventive concept.

### DETAILED DESCRIPTION

Example embodiments of the inventive concepts will now be described more fully with reference to the accompanying drawings, in which example embodiments are shown. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

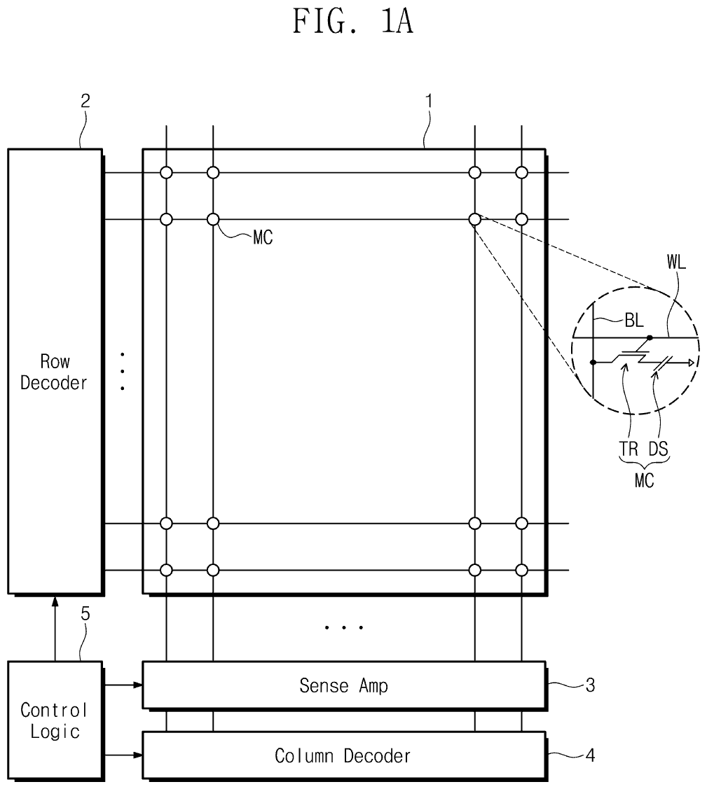

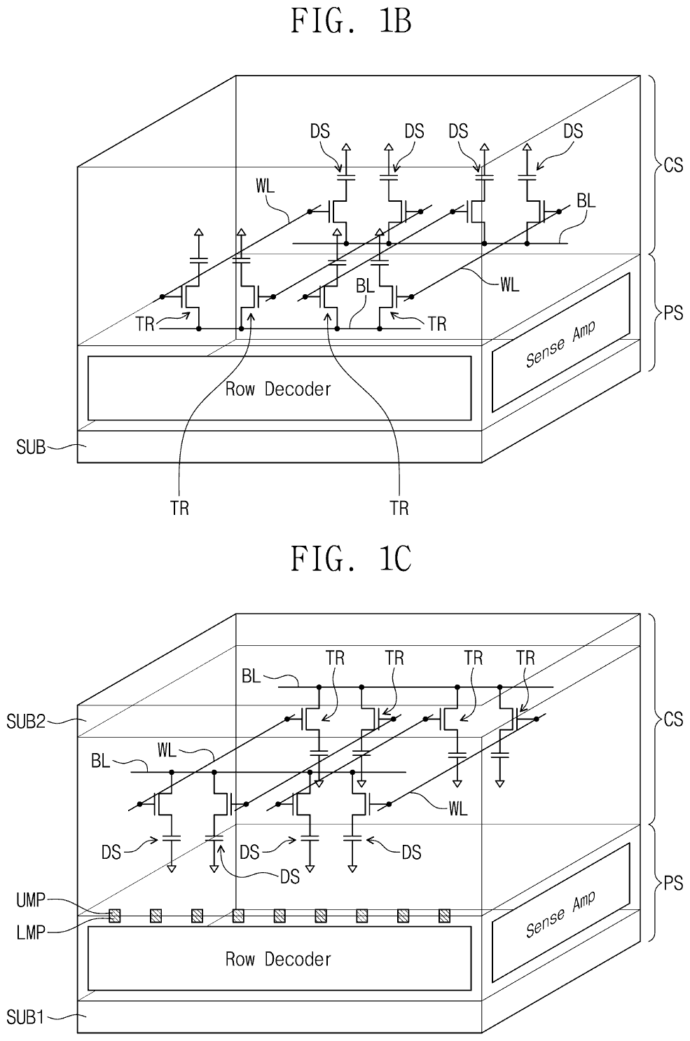

FIG. 1A is a block diagram illustrating a semiconductor device according to an example embodiment of the inventive concept.

Referring to FIG. 1A, a semiconductor device may include a memory cell array 1, a row decoder 2, a sense amplifier 3, a column decoder 4, and a control logic 5.

The memory cell array 1 may include a plurality of memory cells MC, which are two- or three-dimensionally arranged. Each of the memory cells MC may be provided between a word line WL and a bit line BL, which are not parallel to each other.

Each of the memory cells MC may include a selection element TR and a data storage element DS. The selection element TR and the data storage element DS may be electrically connected to each other. The selection element TR may be connected to both the word line WL and the bit line BL. In other words, the selection element TR may be provided at an intersection of the word and bit lines WL and BL.

The selection element TR may include a field effect transistor. The data storage element DS may include a capacitor, a magnetic tunnel junction pattern, or a variable resistor. As an example, the selection element TR may be a transistor whose gate, source, and drain terminals are connected to the word line WL, the bit line BL, and the data storage element DS, respectively.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information.

The control logic 5 may generate control signals, which are used to control an operation of writing or reading data to or from the memory cell array 1.

FIGS. 1B and 1C are perspective views illustrating a semiconductor device according to an embodiment of the inventive concept.

Referring to FIGS. 1B and 1C, a semiconductor device may include a peripheral circuit structure PS and a cell array structure CS connected to the peripheral circuit structure PS.

The peripheral circuit structure PS may include core and peripheral circuits, which are formed on a substrate SUB. The core and peripheral circuits may include the row and column decoders 2 and 4, the sense amplifier 3, and the control logics 5 described with reference to FIG. 1A.

The cell array structure CS may include the memory cell array 1, in which the memory cells MC are two-dimensional or three-dimensionally arranged (e.g., see FIG. 1A). Each of the memory cells MC of FIG. 1A may include the selection element TR and the data storage element DS, as described above.

In an embodiment, the selection element TR of each of the memory cells MC of FIG. 1A may include a vertical channel transistor (VCT). The vertical channel transistor may include a channel region whose lengthwise direction is substantially normal to a top surface of the substrate SUB. The data storage element DS of each of the memory cells MC of FIG. 1A may include a capacitor.

In the embodiment of FIG. 1B, the elements of the peripheral circuit structure PS may be provided on the substrate SUB, and the cell array structure CS may be provided on the peripheral circuit structure PS.

In the embodiment of FIG. 1C, the elements of the peripheral circuit structure PS may be provided on a first substrate SUB1, and the elements of the cell array structure CS may be provided on a second substrate SUB2. The first and second substrates SUB1 and SUB2 may face each other.

First metal pads LMP may be provided in the uppermost portion of the peripheral circuit structure PS. The first metal pads LMP may be electrically connected to the core and peripheral circuits (e.g., row decoder 2, sense amplifier 3, column decoder 4, and control logic 5) of FIG. 1A.

Second metal pads UMP may be provided in the lowermost portion of the cell array structure CS. The second metal pads UMP may be electrically connected to the memory cell array 1 of FIG. 1A. The second metal pads UMP may be directly bonded to (i.e., in direct contact with) the first metal pads LMP of the peripheral circuit structure PS.

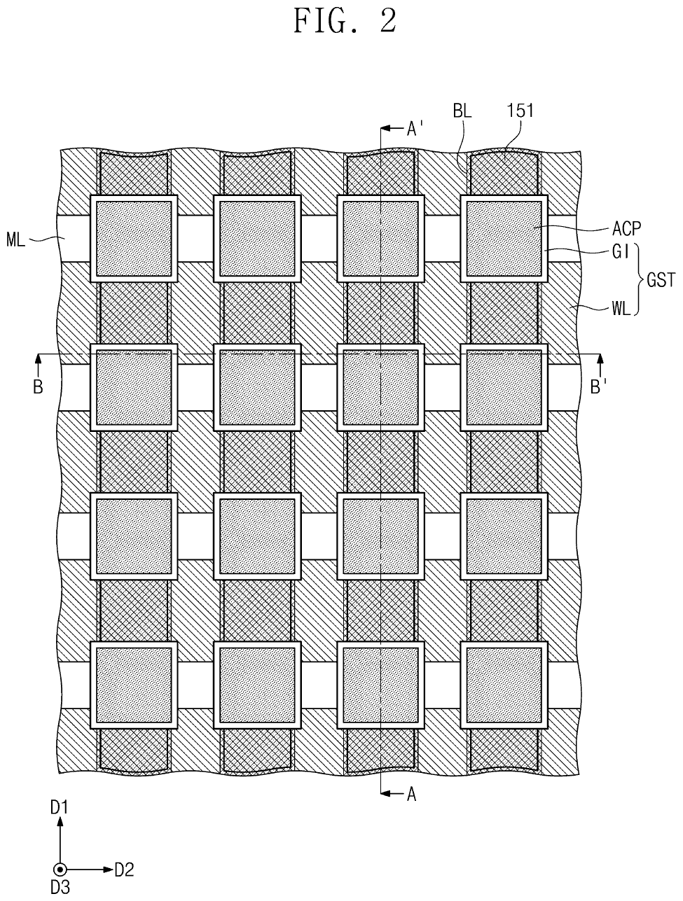

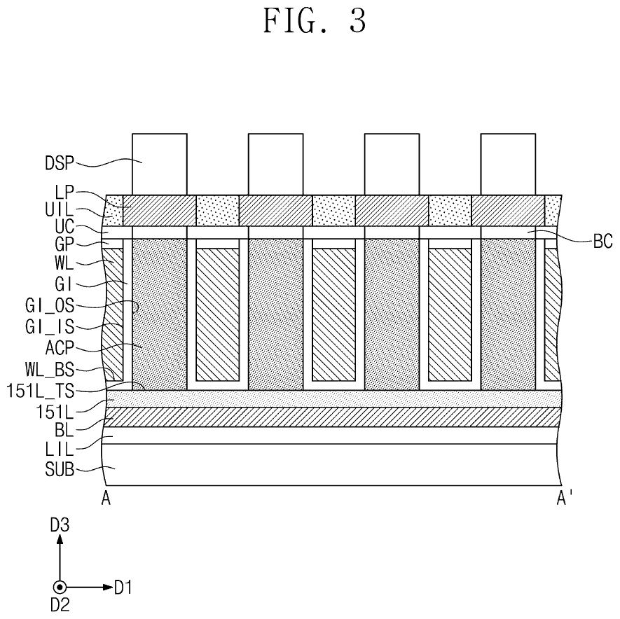

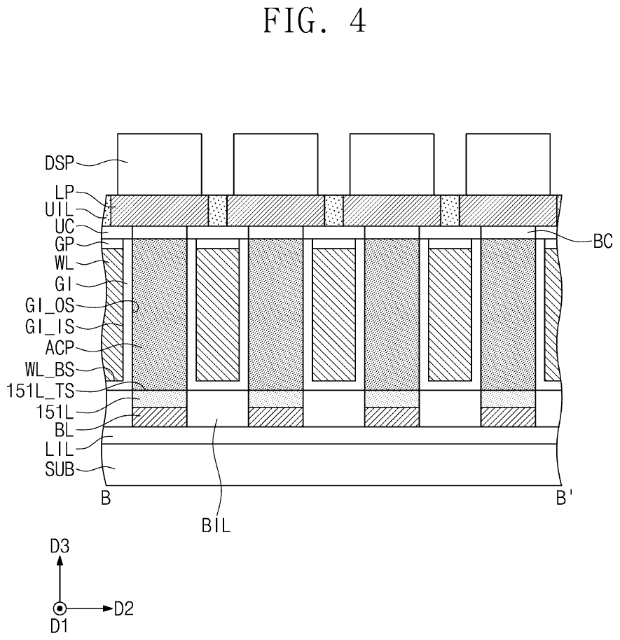

FIG. 2 is a plan view illustrating a semiconductor device according to an example embodiment of the inventive concept. FIG. 3 is a sectional view taken along a line A-A′ of FIG. 2. FIG. 4 is a sectional view taken along a line B-B′ of FIG. 2.

Referring to FIGS. 2 to 4, a lower insulating layer LIL may be provided on the substrate SUB. The substrate SUB may be a plate-shaped structure that is extended parallel to a plane defined by a first direction D1 and a second direction D2. The first and second directions D1 and D2 may not be parallel to each other. In an embodiment, the first and second directions D1 and D2 may be horizontal directions that are orthogonal to each other. A third direction D3 may be perpendicular to the first and second directions D1 and D2. The third direction D3 may be perpendicular to the top surface of the substrate SUB. The lower insulating layer LIL may include an insulating material. In an embodiment, the lower insulating layer LIL may be formed of or include an oxide material.

In an embodiment, the peripheral circuit structure PS described with reference to FIG. 1B may be provided between the substrate SUB and the lower insulating layer LIL. In an embodiment, an integrated circuit (e.g., a logic device) may be provided between the substrate SUB and the lower insulating layer LIL.

The bit lines BL may be provided on the lower insulating layer LIL to extend lengthwise and in parallel in the first direction D1. The bit lines BL may contact an upper surface of the lower insulating layer LIL. The bit lines BL may be arranged in the second direction D2. The bit lines BL may be spaced apart from each other in the second direction D2.

The bit lines BL may include a conductive material. In an embodiment, the bit line BL may be formed of or include at least one of doped polysilicon, metallic materials (e.g., Al, Cu, Ti, Ta, Ru, W, Mo, Pt, Ni, and Co), conductive metal nitride materials (e.g., TiN, TaN, WN, NbN, TiAlN, TiSiN, TaSiN, and RuTiN), conductive metal silicide materials, or conductive metal oxide materials (e.g., PtO, RuO₂, IrO₂, SrRuO₃ (SRO), (Ba,Sr) RuO₃ (BSRO), CaRuO₃ (CRO), and LSCo), but the inventive concept is not limited to this example. The bit line BL may be a single- or multi-layered structure formed of the afore-described materials. In an embodiment, the bit line BL may include a two-dimensional semiconductor material (e.g., graphene, carbon nanotube, or combinations thereof).

A lower intervening structure 151L may be provided on the bit line BL. The lower intervening structure 151L may be at least partially overlapped with the bit line BL in a vertical direction (e.g., the third direction D3). In an embodiment, each of the lower intervening structures 151L may extend lengthwise in the first direction D1, on a corresponding one of the bit lines BL. In another embodiment, unlike the structure shown in FIGS. 2 and 3, each of the lower intervening structures 151L may be arranged to be overlapped with a channel layer ACP to be described below in the third direction D3, and in this case, some of the lower intervening structures 151L may be spaced apart from each other in the first direction D1, on one bit line BL. The lower intervening structure 151L may be formed of or include amorphous silicon. The lower intervening structure 151L may include hydrogen. The lower intervening structures 151L may be respectively interposed between the channel layers ACP and the bit lines BL, and in this case, the resistance performance of the semiconductor device may be improved.

A bit line insulating layer BIL may be provided on the lower insulating layer LIL. The bit line insulating layer BIL may contact an upper surface of the lower insulating layer LIL. The bit line insulating layer BIL may include an insulating material. The bit line insulating layer BIL may be interposed between the bit lines BL. The bit line insulating layer BIL may include a portion interposed between the lower intervening structures 151L. The bit line insulating layer BIL may fill a region between side surfaces of the bit lines BL and the lower intervening structures 151L. The bit line insulating layer BIL may be in contact with the side surfaces of the bit lines BL and the side surface of the lower intervening structure 151L. Upper surfaces of the bit line insulating layer BIL may be coplanar with upper surfaces of the lower intervening structure 151L.

The lower intervening structure 151L may be provided. The lower intervening structure 151L may include a portion, which is overlapped with the bit line BL and the channel layer ACP in the third direction D3. As an example, each of channel layers ACP, which will be described below, may be aligned to a corresponding one of the bit lines BL and a corresponding one of the lower intervening structures 151L in the third direction D3. A top surface 151_TS of the lower intervening structure 151L may include a portion in contact with the channel layer ACP and a portion in contact with a gate insulating layer GI. A bottom surface of the lower intervening structure 151L may be in contact with the bit line BL. The side surface of the lower intervening structure 151L may be in contact with the bit line insulating layer BIL.

A distance from the substrate SUB to the top surface 151_TS of the lower intervening structure 151L may be smaller than a distance from the substrate SUB to a bottom surface WL_BS of the word line WL. The distance from the substrate SUB to the top surface 151_TS of the lower intervening structure 151L may be larger than a distance from the substrate SUB to the top surface of the bit line BL.

The channel layers ACP may be provided on the lower intervening structure 151L. A plurality of the channel layers ACP may be in contact with each of the lower intervening structures 151L. The channel layers ACP provided on the lower intervening structure 151L may be arranged in the first direction D1. The channel layer ACP may be spaced apart from the bit line BL.

The channel layer ACP may include a semiconductor material. The channel layer ACP may be formed of or include at least one of oxide semiconductor materials (e.g., InGaZnO, InGaSiO, InSnZnO, InZnO, ZnO, ZnSnO, ZnON, ZrZnSnO, SnO, HfInZnO, GaZnSnO, AlZnSnO, YbGaZnO, and InGaO), but the inventive concept is not limited to this example. In an embodiment, the channel layer ACP may include indium gallium zinc oxide (IGZO). The channel layer ACP may be formed of or include at least one of indium gallium zinc oxide (IGZO), indium gallium tin oxide (IGTO), zinc oxide (ZnO), indium zinc oxide (IZO), indium zinc tin oxide (IZTO), or zinc tin oxide (ZTO). The channel layer ACP may have a single- or muti-layered structure of the oxide semiconductor material. The channel layer ACP may be formed of or include an amorphous, single-crystalline, or poly-crystalline oxide semiconductor material. In an embodiment, the channel layer ACP may have a band gap energy that is greater than that of silicon. For example, the channel layer ACP may have the band gap energy of about 1.5 eV to 5.6 eV. In an embodiment, when the channel layer ACP has a band gap energy of about 2.0 eV to 4.0 eV, the channel layer ACP may have an optimized channel performance. For example, the channel layer ACP may have a polycrystalline or amorphous structure, but the inventive concept is not limited to this example. In an embodiment, the channel layer ACP may include a two-dimensional semiconductor material (e.g., graphene, carbon nanotube, or combinations thereof). The lower intervening structure 151L and the channel layer ACP may further include hydrogen.

The word lines WL may be provided. The word line WL may be provided on the gate insulating layer GI. The word line WL may be in contact with the gate insulating layer GI. The word lines WL may be spaced apart from each other in the first direction D1. The word line WL1 may extend lengthwise in the second direction D2.

The word line WL may include a conductive material. The word line WL may be formed of or include at least one of doped polysilicon, metallic materials (e.g., Al, Cu, Ti, Ta, Ru, W, Mo, Pt, Ni, or Co), conductive metal nitride materials (e.g., TiN, TaN, WN, NbN, TiAlN, TiSiN, TaSiN, or RuTiN), conductive metal silicide materials, or conductive metal oxide materials, but the inventive concept is not limited to this example. The word line WL may be a single- or multi-layered structure formed of the afore-described materials. In an embodiment, the word line WL may include a two-dimensional semiconductor material (e.g., graphene, carbon nanotube, or combinations thereof).

The gate insulating layer GI may be provided on the side surface of the channel layer ACP. The gate insulating layer GI may include portions, which are interposed between the channel layer ACP and the word line WL, between the channel layer ACP and the lower intervening structure 151L, and between the channel layer ACP and a gate capping layer GP. The gate insulating layer GI may be in contact with the gate capping layer GP. The gate insulating layer GI may be provided between the word line WL and the channel layer ACP. When viewed in a plan view, the gate insulating layer GI may enclose the channel layer ACP. The gate insulating layer GI may include an insulating material. In an embodiment, the gate insulating layer GI may be formed of or include an oxide material.

The gate insulating layer GI may include a first side surface GI_IS and a second side surface GI_OS, which are opposite to each other. The second side surface GI_OS may face the channel layer ACP. The first side surface GI_IS may include a first portion facing the word line WL and a second portion facing a mold layer ML, which will be described below.

The gate insulating layer GI may be in contact with the word line WL. The first side surface GI_IS of the gate insulating layer GI may be in contact with the word line WL. The gate insulating layer GI may be in contact with the channel layer ACP. The second side surface GI_OS of the gate insulating layer GI may be in contact with the channel layer ACP. A bottom surface of the gate insulating layer GI may be in contact with the lower intervening structure 151L and the bit line insulating layer BIL. The gate insulating layer GI may contact a bottom surface WL_BS of the word line WL.

The gate capping layer GP may be provided on the word line WL. A bottom surface of the gate capping layer GP may be in contact with the word line WL, and a side surface of the gate capping layer GP may be in contact with the gate insulating layer GI. Upper surfaces of the gate capping layer GP may be coplanar with upper surfaces of the gate insulating layer and the channel layer ACP. The gate capping layer GP may include an insulating material. In an embodiment, the gate capping layer GP may include a nitride material.

When viewed in a plan view, mold layers ML may be provided between the word lines WL, which are spaced apart from each other. The mold layer ML may be provided between the channel layers ACP, which are adjacent to each other in the second direction D2. For example, first and second channel layers ACP of the channel layers ACP may be spaced apart from each other in the first direction D1, with the first mold layer ML of the mold layers ML interposed therebetween. The mold layer ML may be in contact with the gate insulating layers GI, which are adjacent to each other. A mold layer ML may include an insulating material.

An upper capping layer UC may be provided on the gate capping layer GP. The upper capping layer UC may cover the gate capping layer GP. The upper capping layer UC may be in contact with the gate capping layer GP. The upper capping layer UC may contact an upper surface of the gate insulating layer GI. The upper capping layer UC may include an insulating material. The upper capping layer UC may include a nitride material.

Contact patterns BC may be provided on the channel layers ACP. The contact patterns BC may contact an upper surface of the channel layers ACP. The contact patterns BC may be formed of at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the inventive concept is not limited to this example. When viewed in a plan view, each of the contact patterns BC may have a circular, elliptical, rectangular, square, diamond, or hexagonal shape. The upper capping layer UC may be disposed between the contact patterns BC, which are spaced apart from each other. The upper capping layer UC may contact side surfaces of the contact patterns BC. Upper surfaces of the upper capping layer UC and the contact patterns BC may be coplanar.

Landing pads LP may be provided on the contact patterns BC. The landing pads LP may contact upper surfaces of the contact patterns BC and the upper capping layer UC. The landing pads LP may be overlapped with the channel layer ACP and the lower intervening structure 151L in a vertical direction (e.g., the third direction D3). The landing pads LP may be spaced apart from each other in the first and second directions D1 and D2. The landing pads LP may be in direct contact with the contact patterns BC and may be electrically connected to the contact patterns BC. When viewed in a plan view, the contact pattern BC may be spaced apart from each other in the first and second directions D1 and D2 and may be arranged in a matrix, zigzag, or honeycomb. When viewed in a plan view, each of the landing pads LP may have a circular, elliptical, rectangular, square, diamond, or hexagonal shape.

The landing pads LP may be formed of or include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or combinations thereof, but the inventive concept is not limited to this example.

An upper insulating layer UIL may be provided between the landing pads LP. The upper insulating layer UIL may be provided on the upper capping layer UC. The upper insulating layer UIL may be in contact with a top surface of the upper capping layer UC. The upper insulating layer UIL may separate the landing pads LP from each other. The upper insulating layer UIL may include an insulating material. In an embodiment, the upper insulating layer UIL may include a nitride material.

Data storage patterns DSP may be provided on the landing pads LP, respectively. The data storage pattern DSP may be electrically connected to the channel layer ACP through the landing pad LP.

In an embodiment, the data storage pattern DSP may be a capacitor and may include bottom and top electrodes and a capacitor dielectric layer interposed therebetween. In this case, the bottom electrode may be in contact with the landing pad LP and may have a circular, elliptical, rectangular, square, diamond, or hexagonal shape, when viewed in a plan view.

In an embodiment, the data storage pattern DSP may be a variable resistance pattern whose resistance can be switched to one of at least two states by an electric pulse applied thereto. For example, the data storage pattern DSP may be formed of or include at least one of phase-change materials whose crystal state can be changed depending on an amount of a current applied thereto, perovskite compounds, transition metal oxides, magnetic materials, ferromagnetic materials, or antiferromagnetic materials.

The lower intervening structure 151L, the channel layer ACP, the landing pad LP, and the data storage pattern DSP may be overlapped with each other in the third direction D3.

The lower intervening structure 151L may be overlapped with a portion of the word line WL in the third direction D3. The lower intervening structure 151L may be overlapped with a portion of the gate insulating layer GI in the third direction D3.

According to an embodiment of the inventive concept, the semiconductor device may include the lower intervening structure 151L, which is interposed between the bit line BL and the channel layer ACP and is formed of or include amorphous silicon. In this case, the resistance and thermal stability between the channel layer ACP and the bit line BL may be improved, and thus, the electric characteristics of the semiconductor device may be improved.

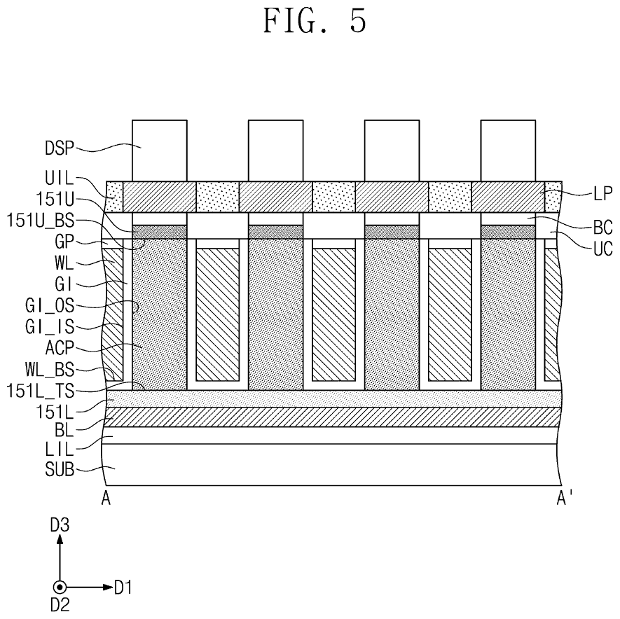

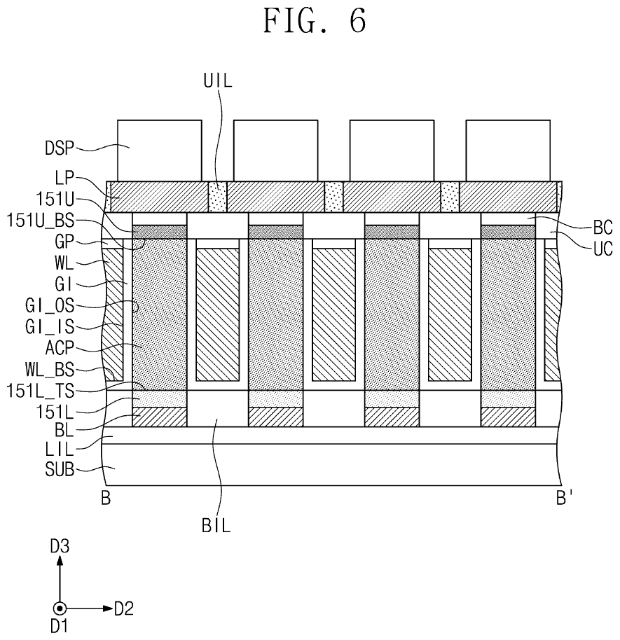

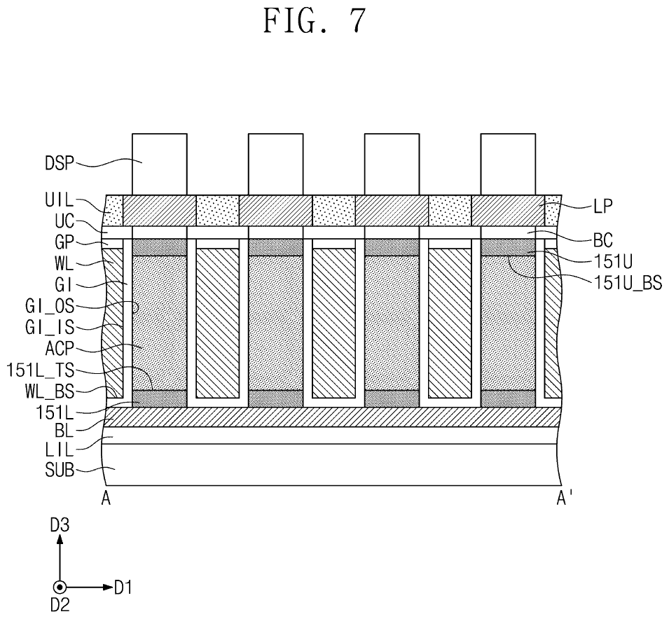

FIG. 5 is a sectional view, which is taken along a line A-A′ of FIG. 2 to illustrate a semiconductor device according to an example embodiment of the inventive concept. FIG. 6 is a sectional view, which is taken along a line B-B′ of FIG. 2 to illustrate a semiconductor device according to an example embodiment of the inventive concept.

The semiconductor device of FIGS. 5 and 6 may be similar to the semiconductor device described with reference to FIGS. 2 to 4, except for the features to be described below. Duplicate descriptions will not be repeated.

Referring to FIGS. 5 and 6, the lower intervening structure 151L may be provided on the bit line BL, the channel layer ACP may be provided on the lower intervening structure 151L, an upper intervening structure 151U may be provided on the channel layer ACP, the contact pattern BC may be provided on the upper intervening structure 151U, and the landing pads LP may be provided on the contact pattern BC.

The upper intervening structure 151U may be disposed between the channel layer ACP and the landing pad LP. The upper intervening structure 151U may be interposed between the channel layer ACP and the contact pattern BC. The upper intervening structure 151U may be in contact with the contact pattern BC. The upper intervening structure 151U may include amorphous silicon.

A bottom surface 151U_BS of the upper intervening structure 151U may be in contact with the channel layer ACP, and a top surface of the upper intervening structure 151U may be in contact with the contact pattern BC. A side surface of the upper intervening structure 151U may be in contact with the upper capping layer UC. The upper intervening structure 151U may not be overlapped with the gate capping layer GP in the third direction D3. In example embodiments, a width in the first direction D1 of the upper intervening structure 151U may be substantially the same as a width in the first direction D1 of the channel layer ACP.

The upper intervening structure 151U may be spaced apart from the bit line BL. The channel layer ACP and the lower intervening structure 151L may be vertically interposed between the upper intervening structure 151U and the bit line BL.

The bit line BL, the lower intervening structure 151L, the channel layer ACP, the upper intervening structure 151U, the contact pattern BC, the landing pad LP, and the data storage pattern DSP may be overlapped with each other in the third direction D3.

The upper intervening structure 151U may include hydrogen. In an embodiment, the upper intervening structure 151U may be formed of or include the same material as the lower intervening structure 151L. In an embodiment, the upper intervening structure 151U may be formed of or include a material different from the lower intervening structure 151L.

A distance from the substrate SUB to the bottom surface 151U_BS of the upper intervening structure 151U may be substantially equal to a distance from the substrate SUB to a top surface of the gate insulating layer GI. In the present specification, the expression “substantially equal” may mean that the difference falls within a margin of error of approximately 5%. A distance from the substrate SUB to the top surface of the upper intervening structure 151U may be larger than a distance from the substrate SUB to the top surface of the gate capping layer GP. The distance from the substrate SUB to the bottom surface 151U_BS of the upper intervening structure 151U may be larger than a distance from the substrate SUB to the bottom surface of the gate capping layer GP. The distance from the substrate SUB to the bottom surface 151U_BS of the upper intervening structure 151U may be larger than a distance from the substrate SUB to the top surface of the word line WL.

In an embodiment, the upper intervening structure 151U and the gate insulating layer GI may be spaced apart from each other. The contact pattern BC and the channel layer ACP may be spaced apart from each other by the upper intervening structure 151U.

According to an embodiment of the inventive concept, the semiconductor device may include the upper intervening structure 151U, which is interposed between the channel layer ACP and the contact pattern BC and is formed of or includes amorphous silicon. In this case, the resistance and thermal stability between the contact pattern BC and the channel layer ACP may be improved, and thus, the electric characteristics of the semiconductor device may be improved.

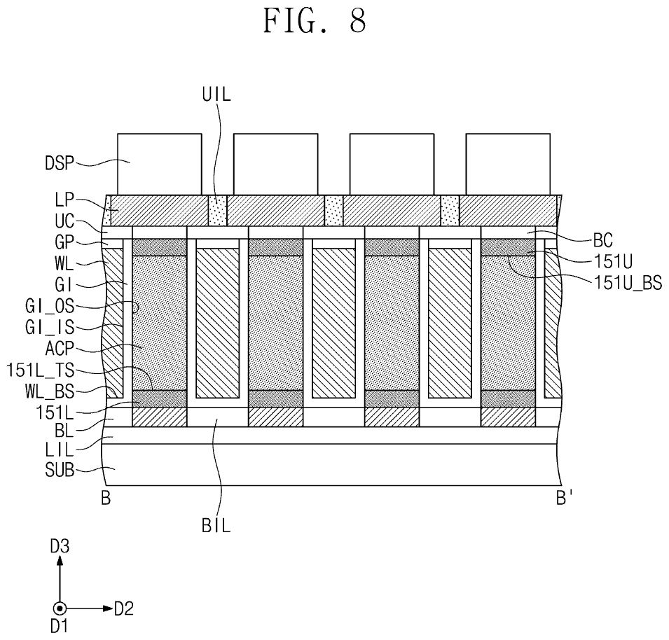

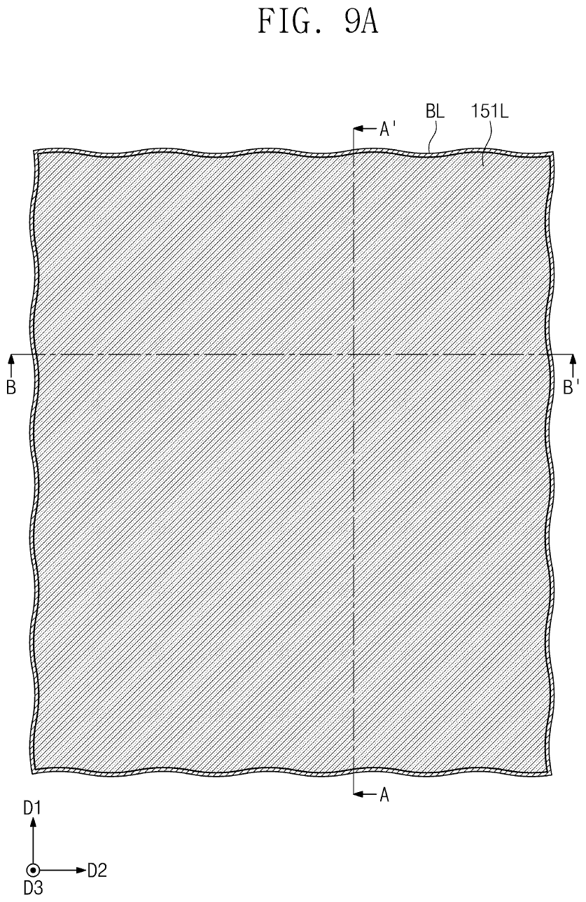

FIG. 7 is a sectional view, which is taken along the line A-A′ of FIG. 2 to illustrate a semiconductor device according to an example embodiment of the inventive concept. FIG. 8 is a sectional view, which is taken along the line B-B′ of FIG. 2 to illustrate a semiconductor device according to an example embodiment of the inventive concept. The semiconductor device of FIGS. 7 and 8 may be similar to the semiconductor device described with reference to FIGS. 5 to 6, except for the features to be described below. Duplicate descriptions will not be repeated.

Referring to FIGS. 7 and 8, the lower intervening structure 151L may be provided on the bit line BL, the gate insulating layer GI may be provided on the bit line BL, the word line WL may be provided on the gate insulating layer GI, the channel layer ACP may be provided on the lower intervening structure 151L, the upper intervening structure 151U may be provided on the channel layer ACP, the contact pattern BC may be provided on the upper intervening structure 151U, and the landing pads LP may be provided on the contact pattern BC.

The top surface of the bit line BL may be in contact with the gate insulating layer GI and the lower intervening structure 151L. The side surface of the lower intervening structure 151L may be in contact with the gate insulating layer GI. The bottom surface of the lower intervening structure 151L may be in contact with the bit line BL. A top surface of the lower intervening structure 151L may be in contact with the channel layer ACP.

The upper intervening structure 151U may be disposed between the channel layer ACP and the landing pad LP. The upper intervening structure 151U may be interposed between the channel layer ACP and the contact pattern BC. The upper intervening structure 151U may include amorphous silicon.

The top surface of the upper intervening structure 151U may be in contact with the contact pattern BC. The bottom surface 151U_BS of the upper intervening structure 151U may be in contact with the channel layer ACP. The side surface of the upper intervening structure 151U may be in contact with the gate insulating layer GI. Upper surfaces of the upper intervening structure 151U may be coplanar with the upper surface of the gate insulating layer GI. The upper intervening structure 151U may be spaced apart from the upper capping layer UC. The upper capping layer UC may be in contact with the contact pattern BC.

The first side surface GI_IS of the gate insulating layer GI may be in contact with the word line WL. The gate insulating layer GI may be in contact with the channel layer ACP, the lower intervening structure 151L, and the upper intervening structure 151U. The second side surface GI_OS, which is opposite to the first side surface GI_IS of the gate insulating layer GI, may be in contact with the channel layer ACP, the lower intervening structure 151L, and the upper intervening structure 151U. The bottom surface of the gate insulating layer GI may be in contact with the bit line BL and the bit line insulating layer BIL.

The upper intervening structure 151U may be spaced apart from the bit line BL. The channel layer ACP and the lower intervening structure 151L may be vertically interposed between the upper intervening structure 151U and the bit line BL.

The bit line BL, the lower intervening structure 151L, the channel layer ACP, the upper intervening structure 151U, the contact pattern BC, the landing pad LP, and the data storage pattern DSP may be overlapped with each other in the third direction D3. The upper intervening structure 151U may include hydrogen.

A distance from the substrate SUB to a top surface 151L_TS of the lower intervening structure 151L may be larger than a distance from the substrate SUB to the bottom surface WL_BS of the word line WL.

The distance from the substrate SUB to the bottom surface 151U_BS of the upper intervening structure 151U may be smaller than the distance from the substrate SUB to the top surface of the gate insulating layer GI. The distance from the substrate SUB to the top surface of the upper intervening structure 151U may be larger than the distance from the substrate SUB to the bottom surface of the gate capping layer GP. The distance from the substrate SUB to the bottom surface 151U_BS of the upper intervening structure 151U may be smaller than the distance from the substrate SUB to the top surface of the gate capping layer GP. The distance from the substrate SUB to the bottom surface 151U_BS of the upper intervening structure 151U may be smaller than the distance from the substrate SUB to the top surface of the word line WL.

The upper intervening structure 151U and the gate capping layer GP may be spaced apart from each other. The contact pattern BC and the channel layer ACP may be spaced apart from each other by the upper intervening structure 151U.

According to an embodiment of the inventive concept, the semiconductor device may include the upper intervening structure 151U, which is interposed between the channel layer ACP and the contact pattern BC and is formed of or includes amorphous silicon. In this case, the resistance and thermal stability between the contact pattern BC and the channel layer ACP may be improved, and thus, the electric characteristics of the semiconductor device may be improved.

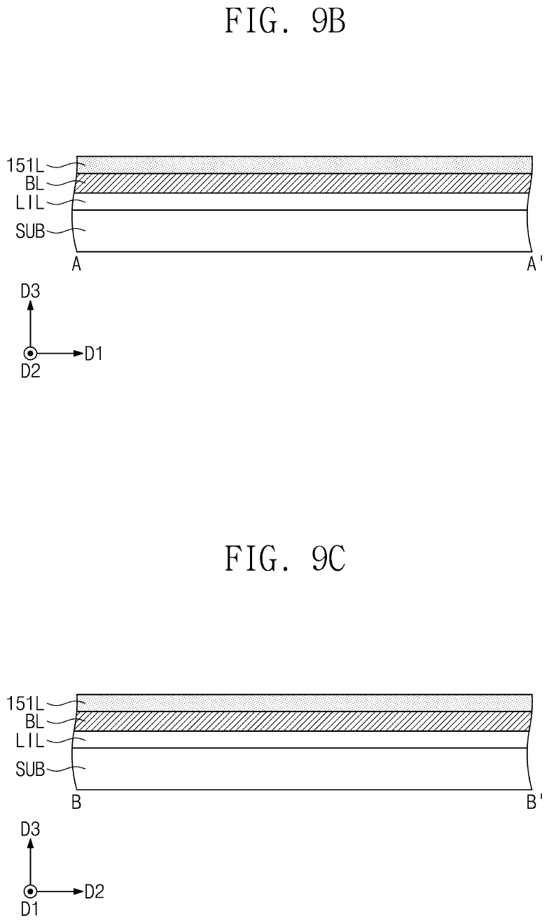

FIGS. 9A, 10A, 11A, 12A, 13A, 14A, and 15A are plan views illustrating a method of fabricating a semiconductor device according to an example embodiment of the inventive concept. FIGS. 9B, 10B, 11B, 12B, 13B, 14B, and 15B are sectional views, which are taken along the line A-A′ of FIG. 2 to illustrate a method of fabricating a semiconductor device, according to an example embodiment of the inventive concept. FIGS. 9C, 10C, 11C, 12C, 13C, 14C, and 15C are sectional views, which are taken along the line B-B′ of FIG. 2 to illustrate a method of fabricating a semiconductor device, according to an example embodiment of the inventive concept. In more detail, FIGS. 9B to 15B and 9C to 15C are sectional views illustrating a method of fabricating the semiconductor device of FIGS. 3 to 4 and the semiconductor device of FIGS. 5 to 6.

Referring to FIGS. 9A, 9B, and 9C, the substrate SUB may be provided. The lower insulating layer LIL may be formed on the substrate SUB, the bit line BL may be formed on the lower insulating layer LIL, and the lower intervening structure 151L may be formed on the bit line BL. The lower insulating layer LIL, the bit line BL, and the lower intervening structure 151L may be formed to have a plate shape extending in the first and second directions D1 and D2.

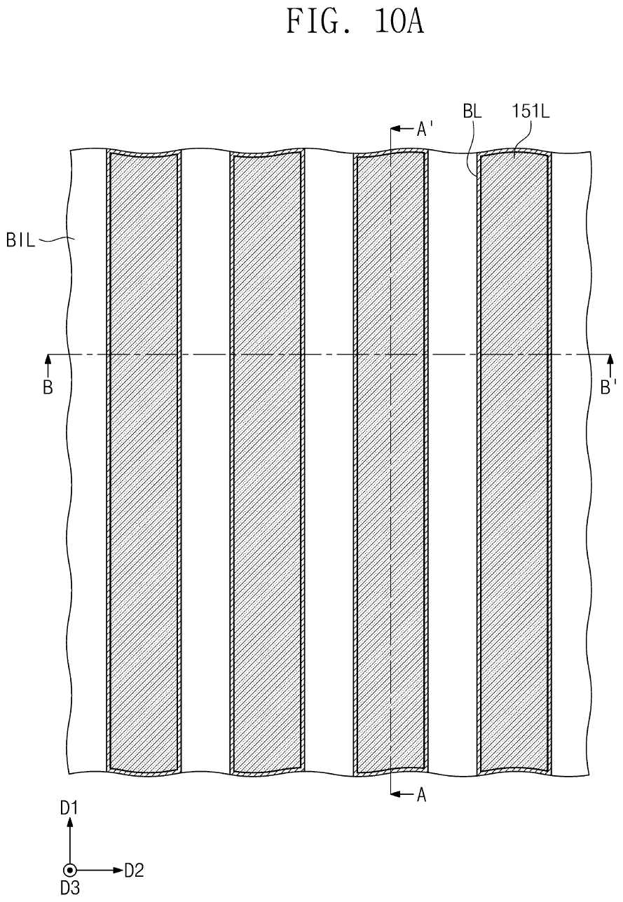

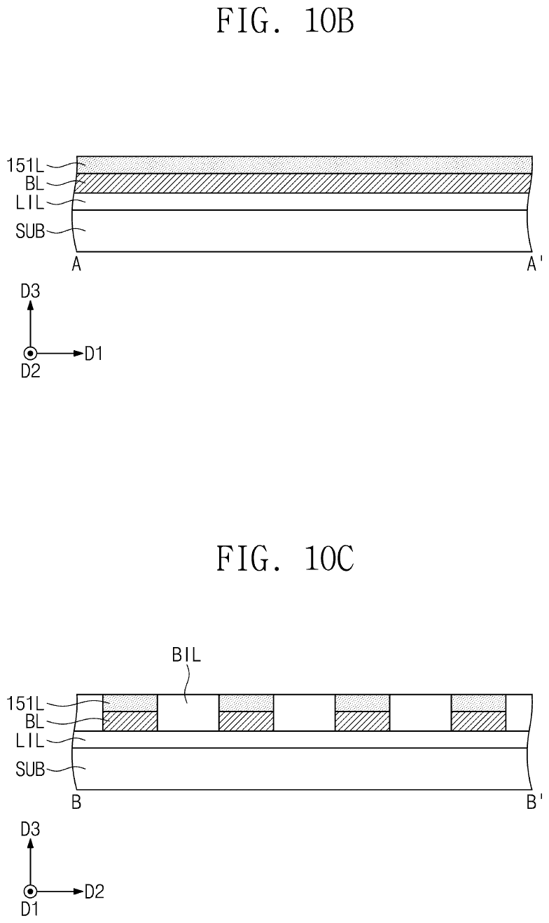

Referring to FIGS. 10A, 10B, and 10C, the bit lines BL and the lower intervening structures 151L may be formed. The bit lines BL and the lower intervening structures 151L may be formed by a patterning process. As a result of the patterning process, the bit lines BL and the lower intervening structures 151L may be formed to extend lengthwise in the first direction D1 and to be spaced apart from each other in the second direction D2. The bit line insulating layer BIL may be formed between the bit lines BL and the lower intervening structures 151L, which are spaced apart from each other.

The bit lines BL and the lower intervening structures 151L may be patterned through a single patterning process. The patterning of the bit lines BL and the lower intervening structures 151L may include forming a mask pattern (not shown) on the bit line BL and the lower intervening structure 151L of FIGS. 9A to 9C, patterning the bit line BL and the lower intervening structure 151L using the mask pattern as an etch mask, and removing the mask pattern. The patterning process may be performed by an anisotropic etching process.

In an embodiment, the bit line insulating layer BIL may be formed to fill a space between the bit lines BL and the lower intervening structures 151L, which are spaced apart from each other by the patterning process.

The bit line insulating layer BIL may be formed on the lower insulating layer LIL, which is exposed through the patterning process. In an embodiment, the formation of the bit line insulating layer BIL may include filling a space between the bit lines BL and the lower intervening structures 151L, which are spaced apart from each other by the patterning process, with the bit line insulating layer BIL. The bit line insulating layer BIL may extend lengthwise in the first direction D1.

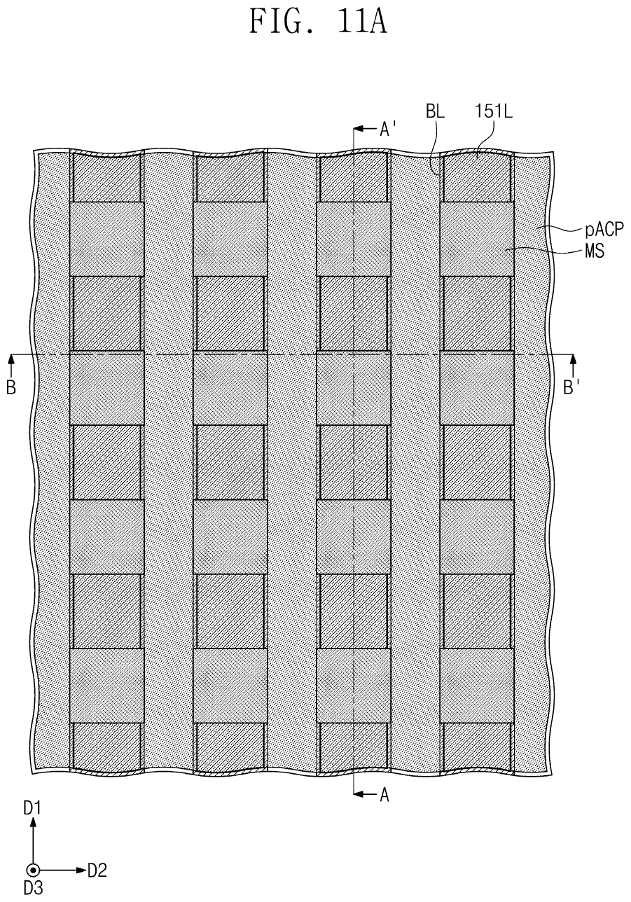

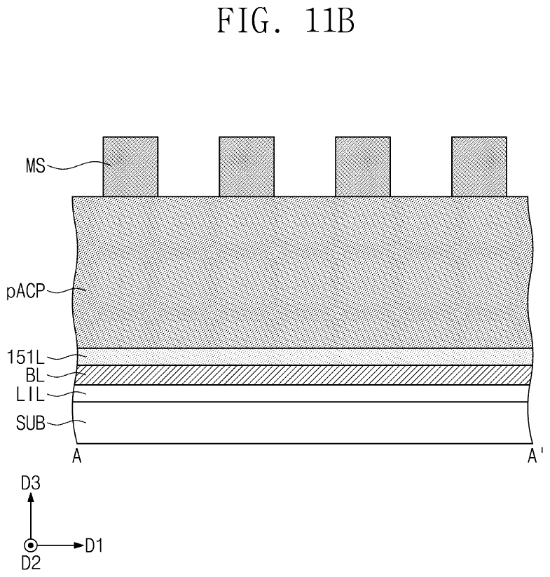

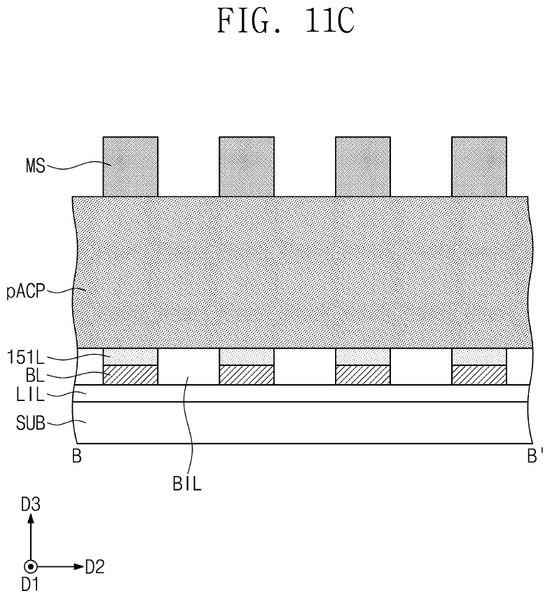

Referring to FIGS. 11A, 11B, and 11C, a preliminary channel layer pACP may be formed on the lower intervening structures 151L and the bit line insulating layer BIL. The preliminary channel layer pACP may include an oxide material. A channel mask pattern MS may be formed on the preliminary channel layer pACP. The channel mask pattern MS may be formed on a region in which the channel layer ACP will be formed. The channel mask pattern MS may be formed to be overlapped with the lower intervening structure 151L in the third direction D3. The channel mask pattern MS may be formed to be overlapped with the bit line BL in the third direction D3.

A plurality of channel mask patterns MS may be formed on the preliminary channel layer pACP, and the channel mask patterns MS may be spaced apart from each other in the first and second directions D1 and D2.

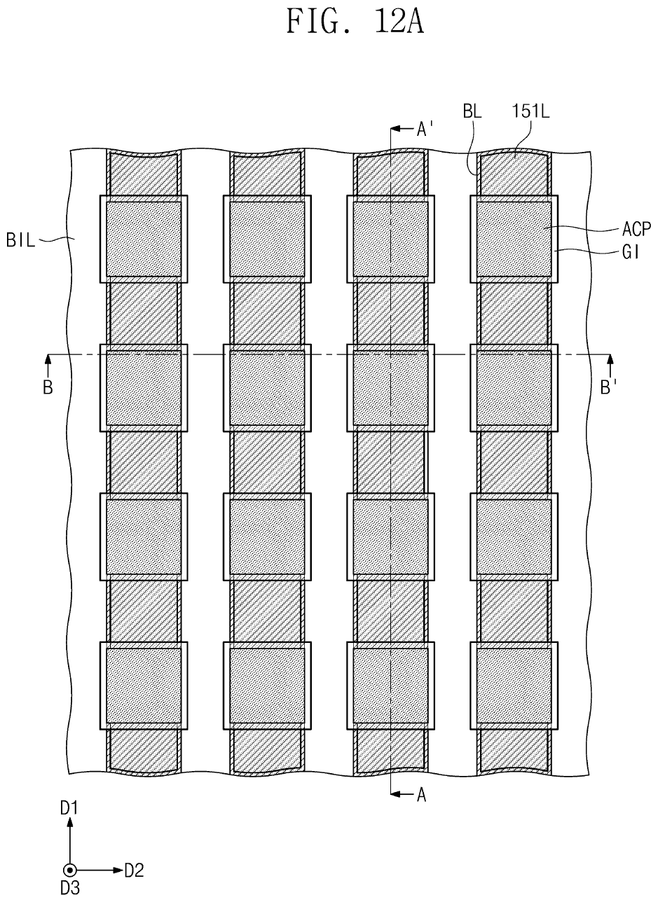

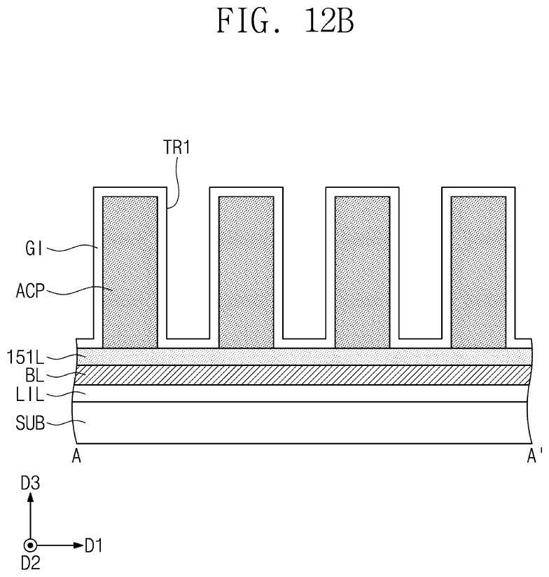

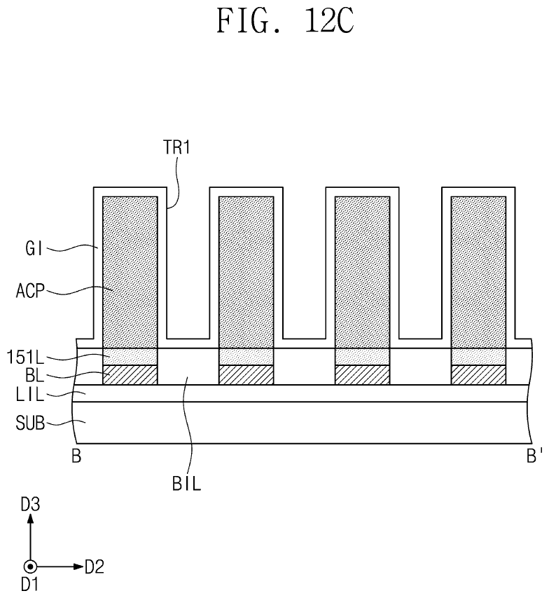

Referring to FIGS. 12A, 12B, and 12C, the preliminary channel layer pACP may be patterned to form the channel layer ACP. The preliminary channel layer pACP may be patterned using the channel mask pattern MS. The patterning of the preliminary channel layer pACP may include patterning the preliminary channel layer pACP using the channel mask pattern MS as an etch mask and removing the channel mask pattern MS. The patterning process may be performed by an anisotropic etching process.

The channel layer ACP may be formed to be spaced apart from each other in the first and second directions D1 and D2. The channel layer ACP may be formed to be overlapped with the bit line BL and the lower intervening structure 151L in the third direction D3.

The gate insulating layer GI may be formed to enclose the side surface of the channel layer ACP. The gate insulating layer GI may be formed to cover an exposed top surface of the lower intervening structure 151L. The gate insulating layer GI may be formed to cover an exposed top surface of the bit line insulating layer BIL. The gate insulating layer GI may be formed along the top surface of the lower intervening structure 151L, the top surface of the bit line insulating layer BIL, and the side and top surfaces of the channel layer ACP. A first trench TR1 may be defined between the channel layers ACP by the gate insulating layer GI. The first trench TR1 may be defined between side surfaces of the gate insulating layer GI.

The formation of the gate insulating layer GI may be achieved using a layer-forming process (e.g., chemical vapor deposition (CVD), physical vapor deposition (PVD), or atomic layer deposition (ALD)) having a good step-coverage property.

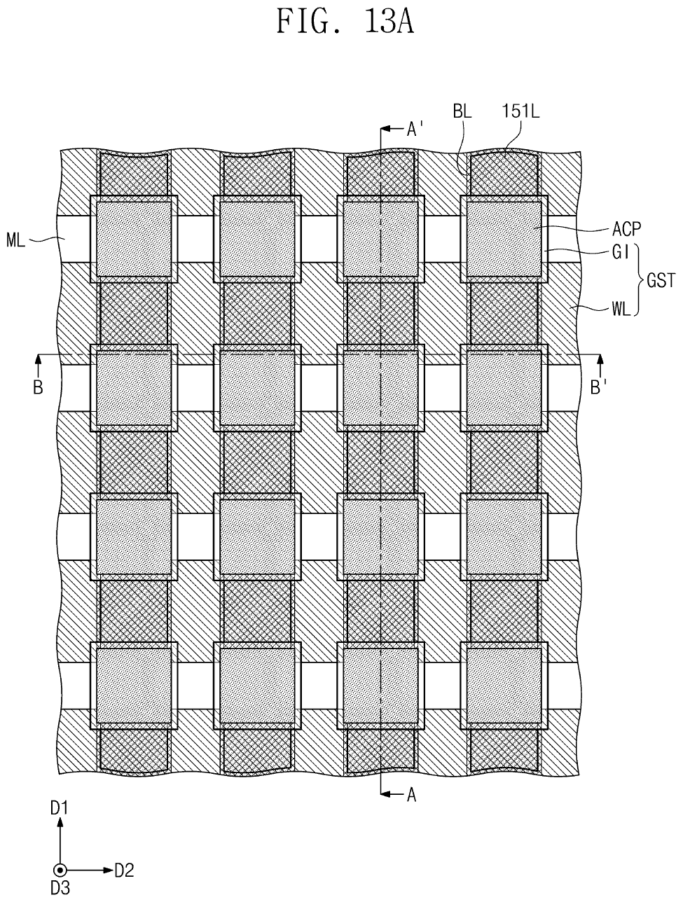

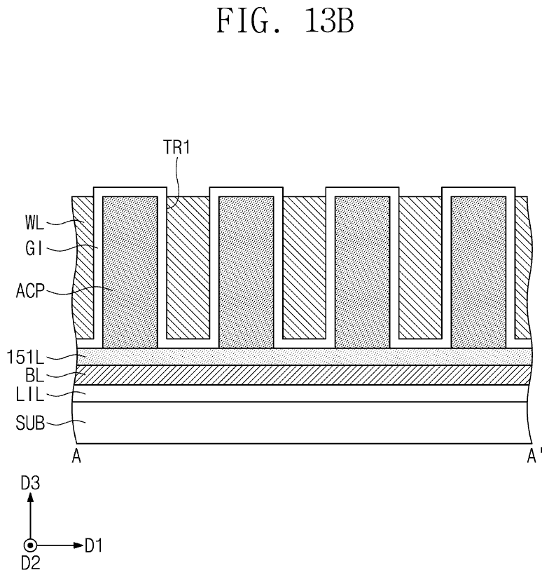

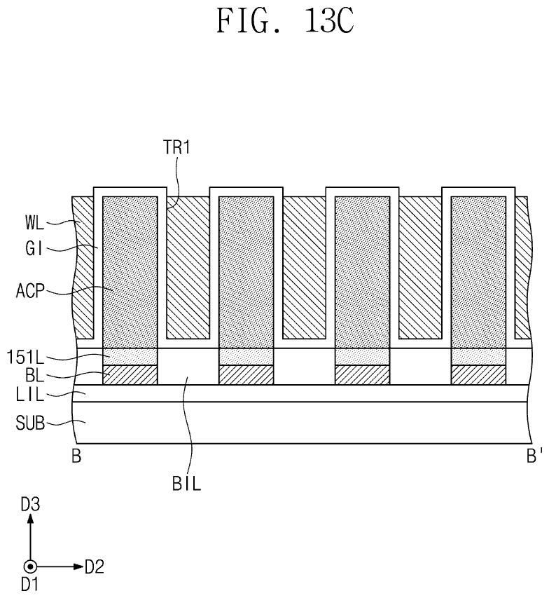

Referring to FIGS. 13A, 13B, and 13C, the word line WL may be formed on the gate insulating layer GI to fill the first trench TR1. A patterning process may be performed to form the word lines WL, which extend lengthwise in the second direction D2 and are spaced apart from each other in the first direction D1.

The mold layer ML may be formed between the word lines WL. In an embodiment, a plurality of mold layers ML may be formed. The mold layer ML may be formed between the gate insulating layers GI, which are adjacent to each other.

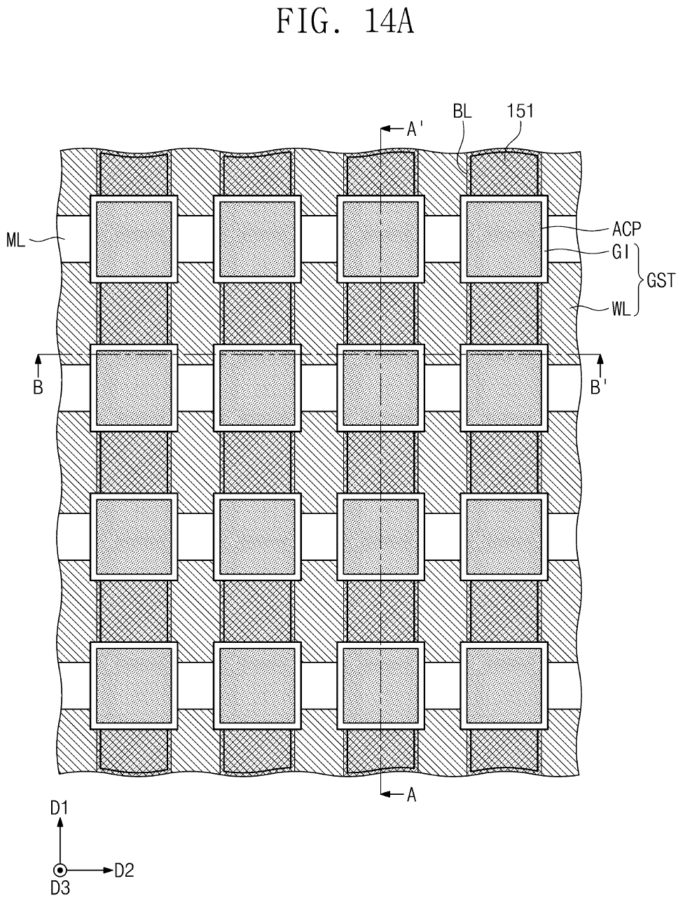

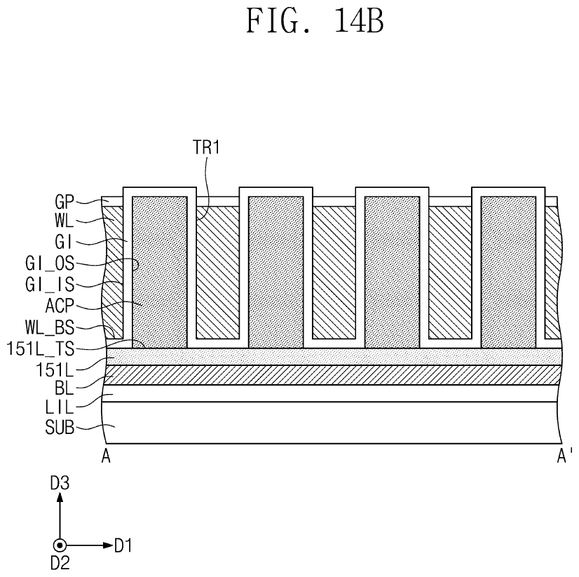

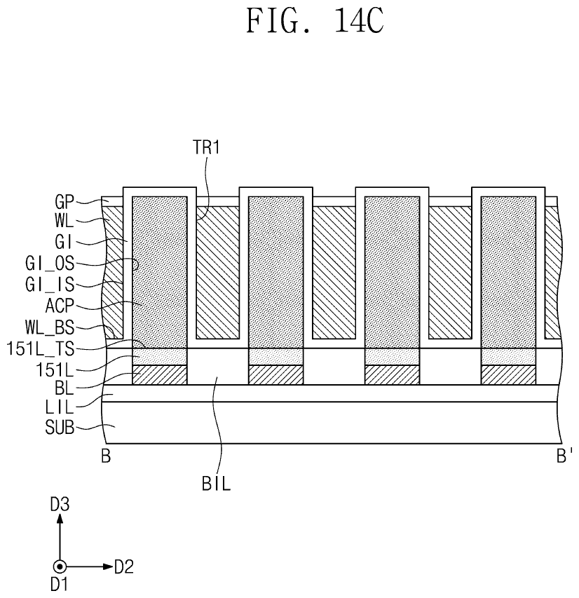

Referring to FIGS. 14A, 14B, and 14C, the gate capping layer GP may be formed on the word lines WL. The gate capping layer GP may be formed to cover the top surfaces of the word lines WL.

Since the gate capping layer GP is formed before a subsequent planarization process on a top surface of the gate insulating layer GI, the first side surface GI_IS of the gate insulating layer GI may be in contact with the word line WL and the gate capping layer GP, and the second side surface GI_OS of the gate insulating layer GI, which is opposite to the first side surface GI_IS, may be in contact with the channel layer ACP.

Since the word line WL is formed after the formation of the lower intervening structure 151L and after the formation of the gate insulating layer GI and the gate insulating layer GI is located between the word line WL and the lower intervening structure 151L, a distance from the substrate SUB to the top surface TS of the lower intervening structure 151L may be smaller than a distance from the substrate SUB to the bottom surface WL_BS of the word line WL.

Referring back to FIGS. 2, 3, and 4, a planarization process may be performed on the gate insulating layer GI and the gate capping pattern GP, after the formation of the gate capping layer GP. As a result of the planarization process, a portion of the gate insulating layer GI, which is overlapped with the channel layer ACP in the third direction D3, may be removed. Next, the contact pattern BC may be formed on the channel layer ACP. The upper capping layer UC may be formed between the contact patterns BC, which are spaced apart from each other.

Next, the landing pads LP may be formed on the contact patterns BC, and the upper insulating layer UIL may be formed between the landing pads LP. The data storage pattern DSP may be formed on the landing pads LP. The semiconductor device of FIGS. 2 to 4 may be formed.

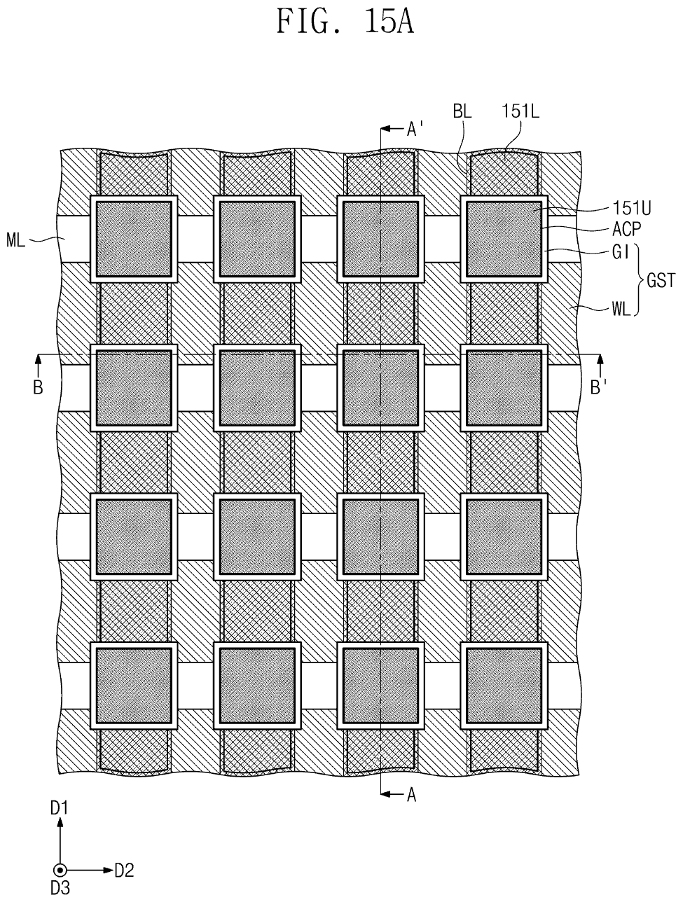

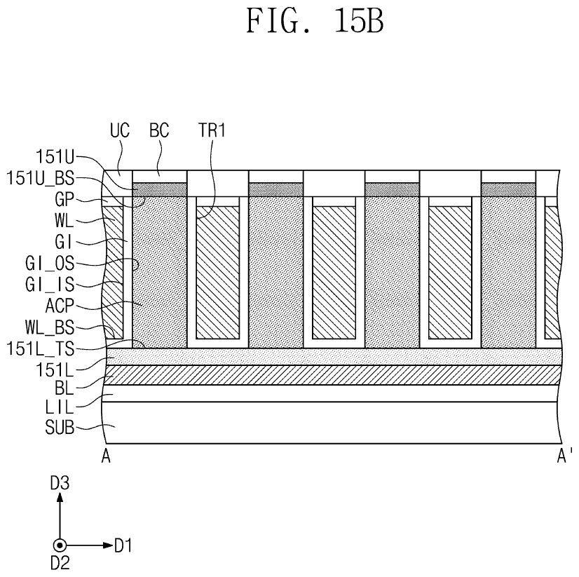

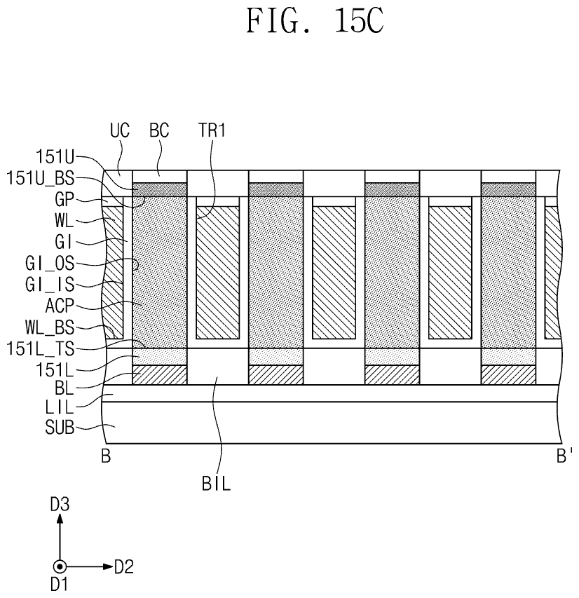

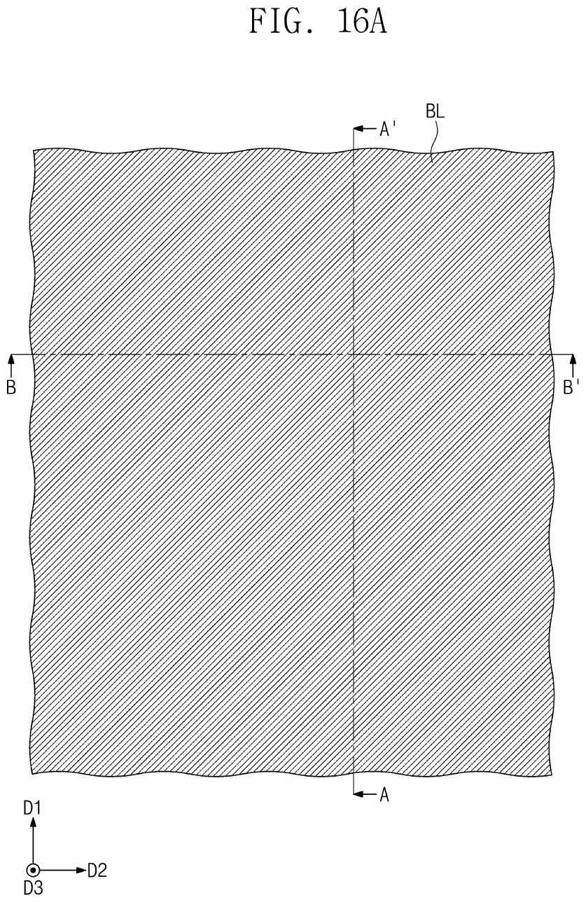

FIGS. 15A, 15B, and 15C illustrate a process that is performed to fabricate the semiconductor device of FIGS. 5 and 6. After the formation of the gate capping layer GP of FIGS. 14A, 14B, and 14C, a planarization process may be performed on the top surface of the gate insulating layer GI and the gate capping pattern GP to remove a portion of the gate insulating layer GI, which is overlapped with the channel layer ACP in the third direction D3.

In an embodiment, the planarization process on the gate insulating layer GI and the gate capping pattern GP may be performed to expose the top surface of the channel layer ACP. As a result of the planarization process, the top surface of the gate insulating layer GI and the top surface of the gate capping pattern GP may be formed at substantially the same height.

The upper intervening structure 151U may be formed on the exposed channel layer ACP, and the contact pattern BC may be formed on the upper intervening structure 151U. The upper intervening structures 151U and the contact patterns BC may be formed in such a way that they are spaced apart from each other in the first and second directions D1 and D2. The upper capping layer UC may be formed between the upper intervening structures 151U and the contact patterns BC. The upper capping layer UC may be formed to cover the gate capping layer GP.

Referring back to FIGS. 5 and 6, the landing pads LP may be formed on the contact patterns BC, and the upper insulating layer UIL may be formed between the landing pads LP.

The data storage pattern DSP may be formed on the landing pads LP. In this case, the semiconductor device may be formed to have the structure of FIGS. 5 and 6.

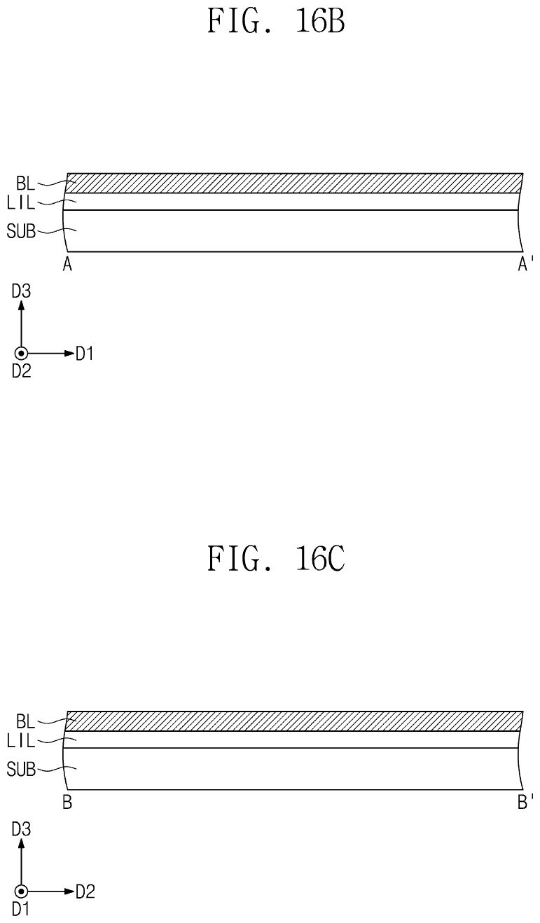

FIGS. 16A, 17A, 18A, 19A, 20A, 21A, and 22A are plan views illustrating a method of fabricating a semiconductor device, according to an example embodiment of the inventive concept. FIGS. 16B, 17B, 18B, 19B, 20B, 21B, and 22B are sectional views, which are taken along the line A-A′ of FIG. 2 to illustrate a method of fabricating a semiconductor device, according to an example embodiment of the inventive concept. FIGS. 16C, 17C, 18C, 19C, 20C, 21C, and 22C are sectional views, which are taken along the line B-B′ of FIG. 2 to illustrate a method of fabricating a semiconductor device, according to an example embodiment of the inventive concept. In detail, FIGS. 16B to 22B and 16C to 22C are sectional views illustrating a method of fabricating the semiconductor device of FIGS. 7 and 8.

Referring to FIGS. 16A, 16B, and 16C, the substrate SUB may be provided. The lower insulating layer LIL may be formed on the substrate SUB, and the bit line BL may be formed on the lower insulating layer LIL. The lower insulating layer LIL and the bit line BL may be formed to have a plate shape extended in the first and second directions D1 and D2.

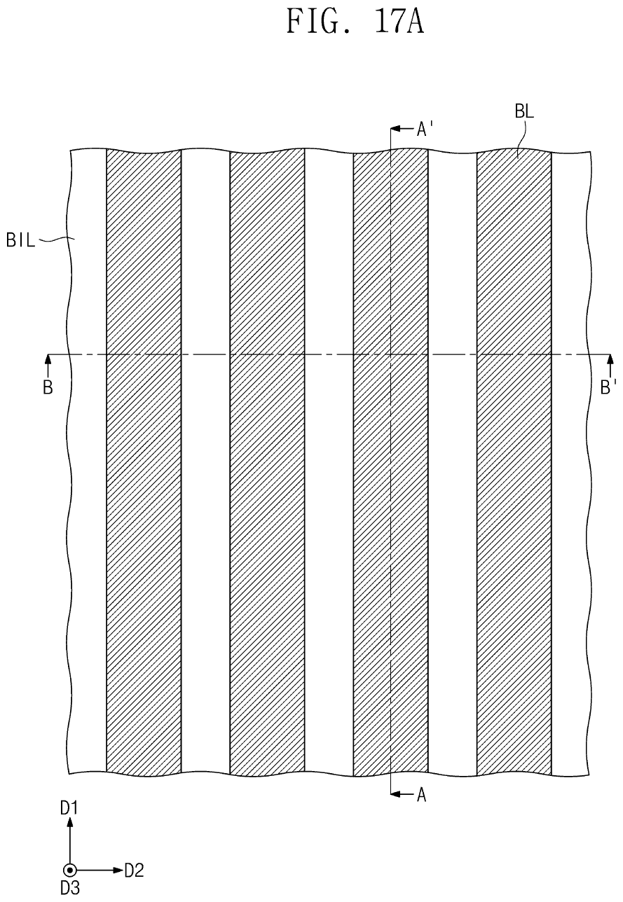

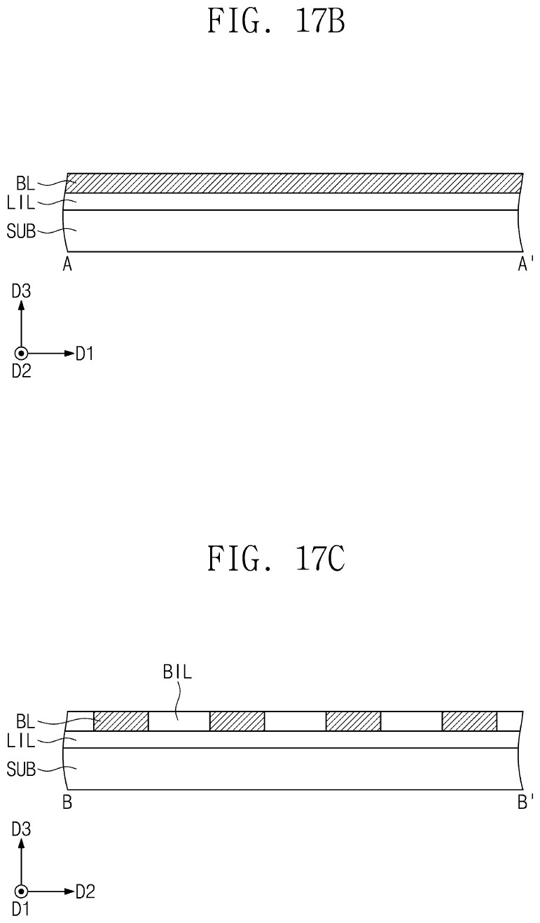

Referring to FIGS. 17A, 17B, and 17C, the bit lines BL and the bit line insulating layer BIL may be formed. In an embodiment, the bit lines BL may be formed by a patterning process. The bit lines BL may be patterned to extend lengthwise in the first direction D1 and to be spaced apart from each other in the second direction D2. The bit line insulating layer BIL may be formed between the bit lines BL, which are spaced apart from each other.

The patterning of the bit lines BL may include forming a mask pattern (not shown) on the bit line BL of FIGS. 16A to 16C, patterning the bit line BL using the mask pattern as an etch mask, and removing the mask pattern. The patterning process may be performed through an anisotropic etching process.

The bit line insulating layer BIL may be formed between the bit lines BL, which are spaced apart from each other by the patterning process, and on the lower insulating layer LIL, which is exposed through the patterning process. In an embodiment, the bit line insulating layer BIL may be formed to fill a space between the bit lines BL, which are spaced apart from each other. The bit line insulating layer BIL may extend lengthwise in the first direction D1.

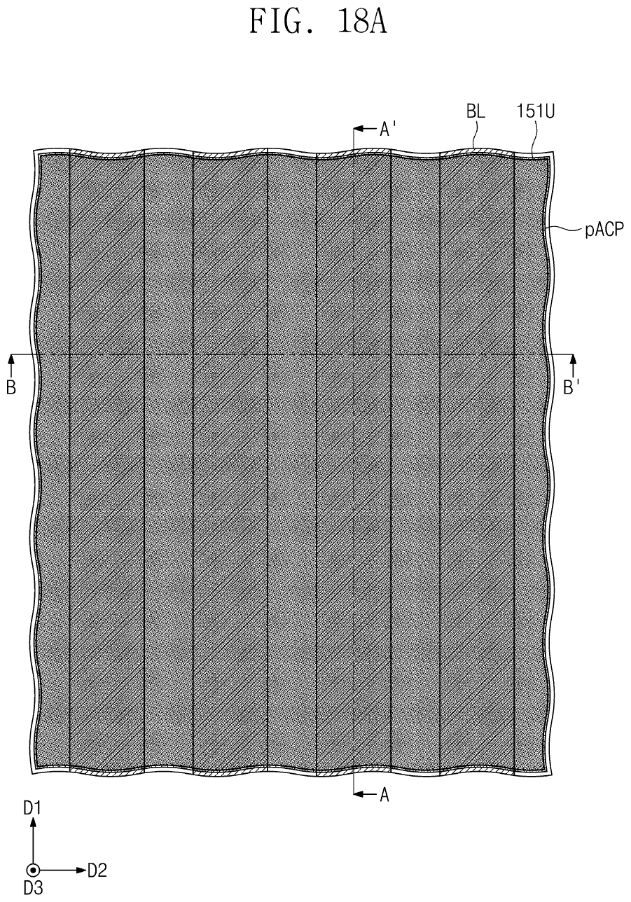

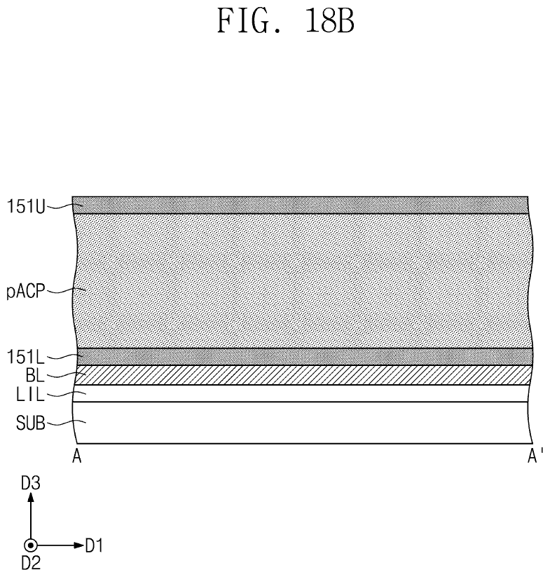

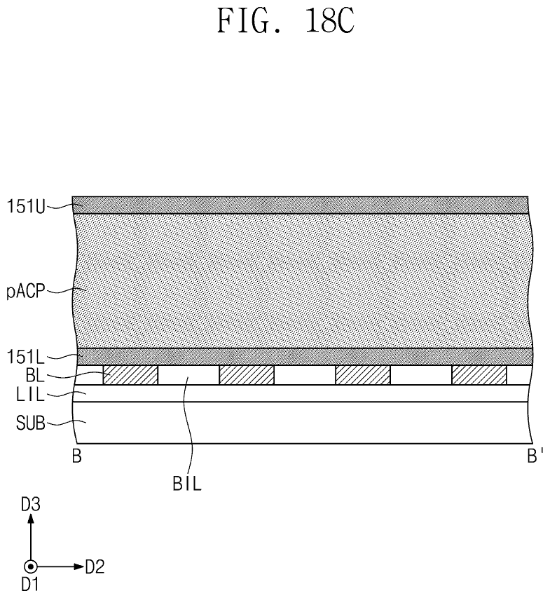

Referring to FIGS. 18A, 18B, and 18C, the lower intervening structure 151L may be formed on the bit line BL and the bit line insulating layer BIL. The preliminary channel layer pACP may be formed on the lower intervening structure 151L. The preliminary channel layer pACP may be formed of or include an oxide material. The upper intervening structure 151U may be formed on the preliminary channel layer pACP. The lower intervening structure 151L, the preliminary channel layer pACP, and the upper intervening structure 151U may be formed to have a plate shape extending in the first and second directions D1 and D2.

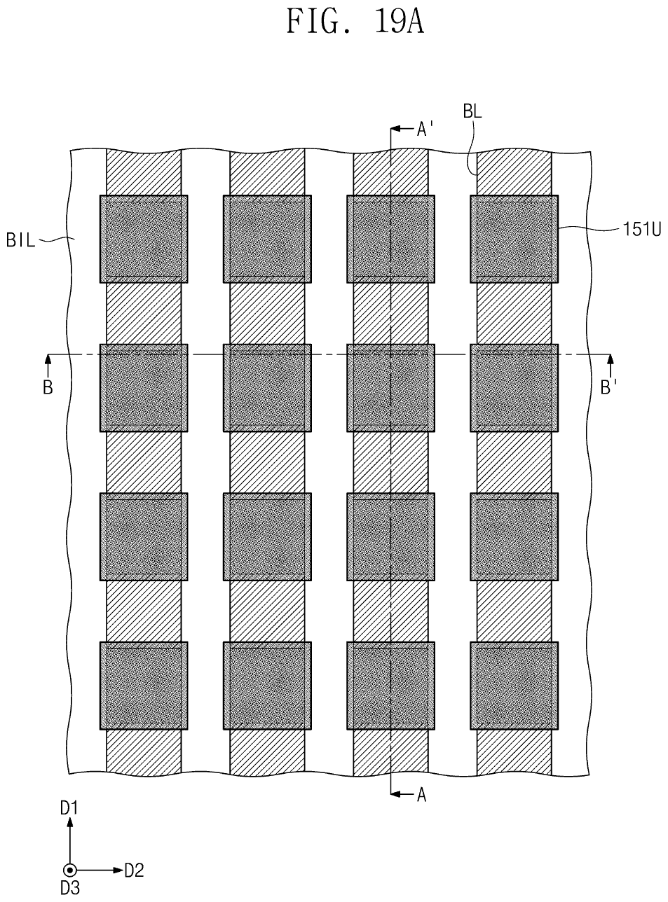

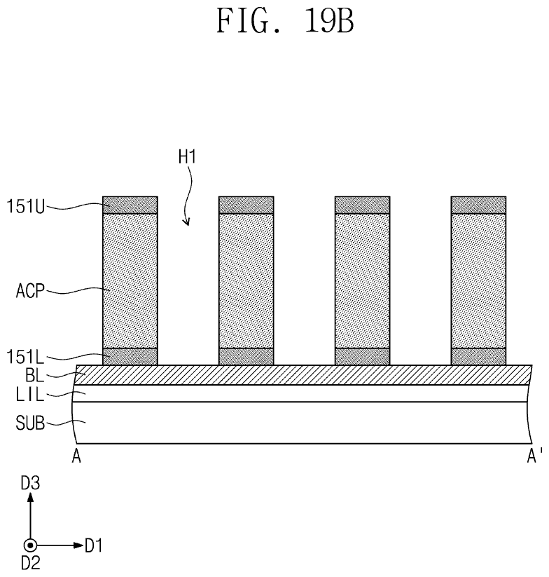

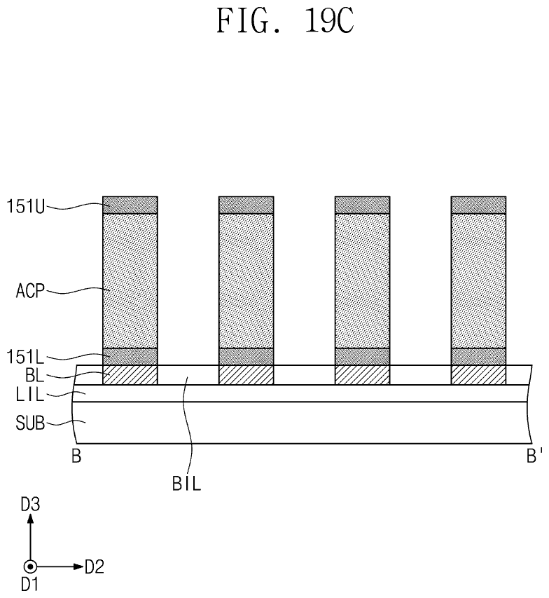

Referring to FIGS. 19A, 19B, and 19C, the lower intervening structures 151L, the preliminary channel layer pACP, and the upper intervening structures 151U may be patterned simultaneously.

The patterning process may include forming a mask pattern (not shown) on the lower intervening structure 151L, the preliminary channel layer pACP, and the upper intervening structure 151U, patterning the lower intervening structure 151L, the preliminary channel layer pACP, and the upper intervening structure 151U using the mask pattern as an etch mask, and removing the mask pattern. The patterning process may be performed by an anisotropic etching process.

As a result of the patterning process, the lower intervening structures 151L, the channel layers ACP, and the upper intervening structures 151U, which are overlapped with each other in the third direction D3, may be formed to be spaced apart from each other in the first and second directions D1 and D2. The lower intervening structures 151L, the channel layers ACP, and the upper intervening structures 151U may be patterned to be overlapped with the bit line BL in the third direction D3.

The lower intervening structures 151L, the channel layers ACP, and the upper intervening structures 151U may be patterned simultaneously to form a first hole H1. The first hole H1 may be an empty space, which is formed between the bit line BL, the bit line insulating layer BIL, the channel layers ACP, and the lower intervening structures 151L through the patterning process. The top surface of the bit line BL, the side surface of the channel layers ACP, the side surface of the lower intervening structures 151L, and the side surface of the upper intervening structures 151U may be exposed by the first hole H1.

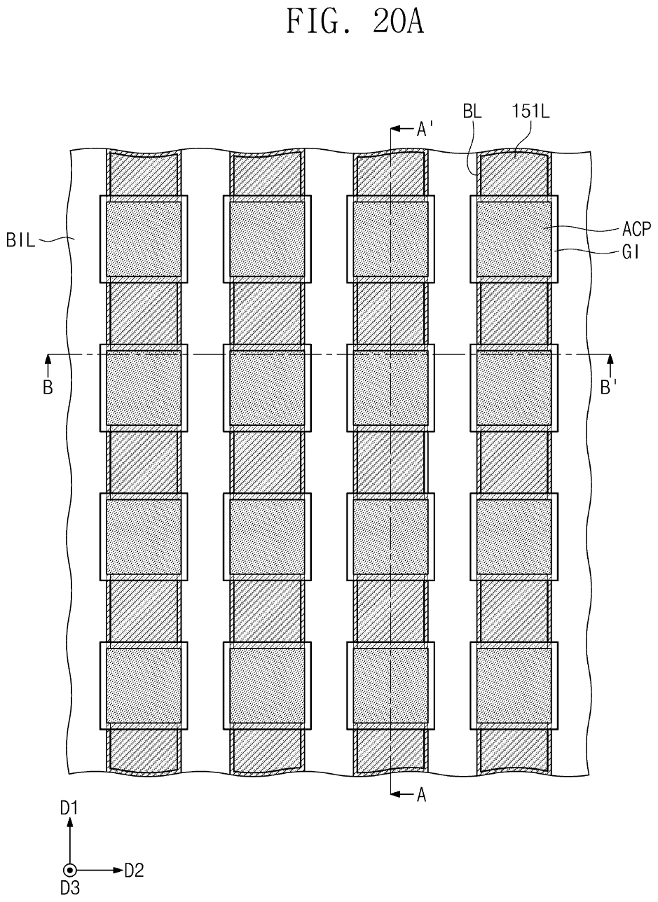

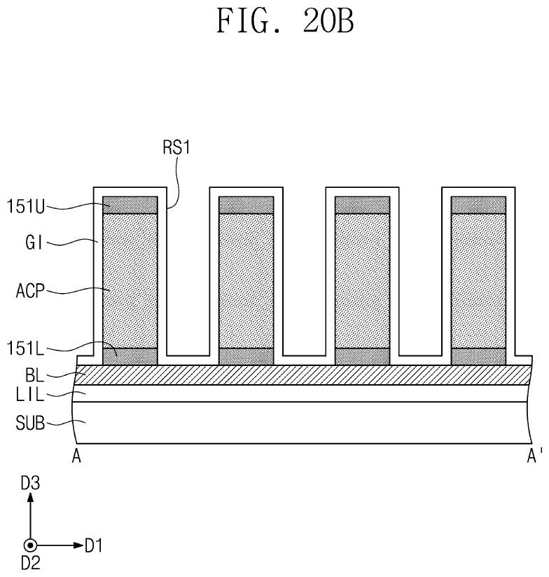

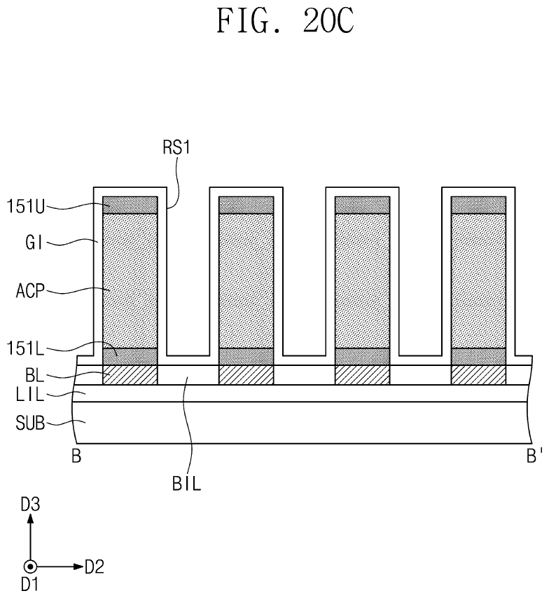

Referring to FIGS. 20A, 20B, and 20C, the gate insulating layer GI may be formed along the first hole H1. The gate insulating layer GI may be formed along exposed surfaces of the lower intervening structures 151L, the channel layer ACP, the upper intervening structures 151U, and the upper intervening structures 151U. The gate insulating layer GI may cover the exposed top surface of the bit line BL and the exposed top surface of the bit line insulating layer BIL.

The formation of the gate insulating layer GI may be achieved using a layer-forming process (e.g., chemical vapor deposition (CVD), physical vapor deposition (PVD), or atomic layer deposition (ALD)) having a good step-coverage property. Since the gate insulating layer GI is formed along the first hole H1, a first recess RS1 may be formed. The first recess RS1 may be an empty space that is defined between the channel layers ACP by the gate insulating layer GI.

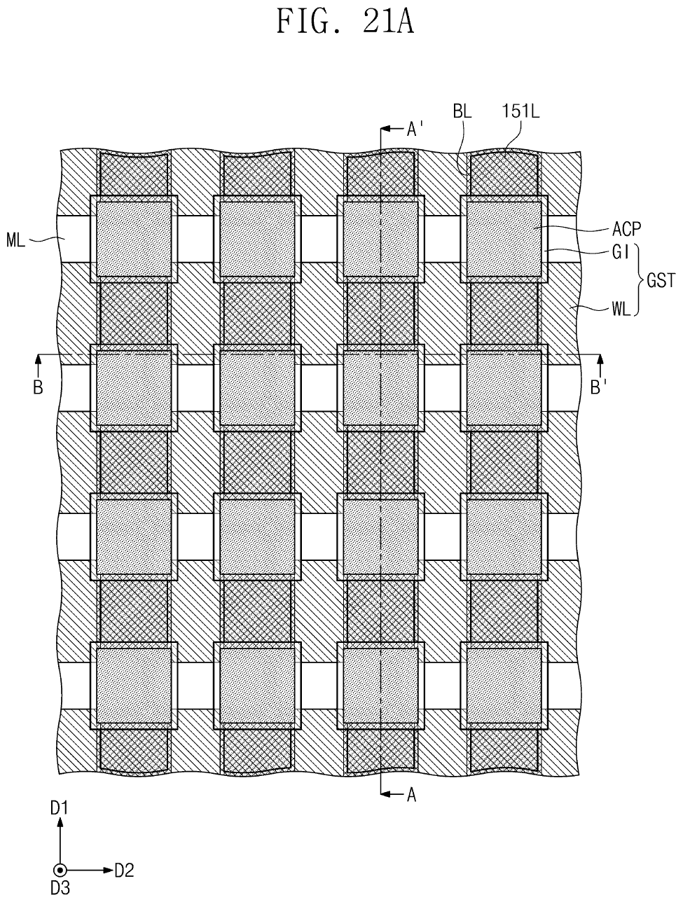

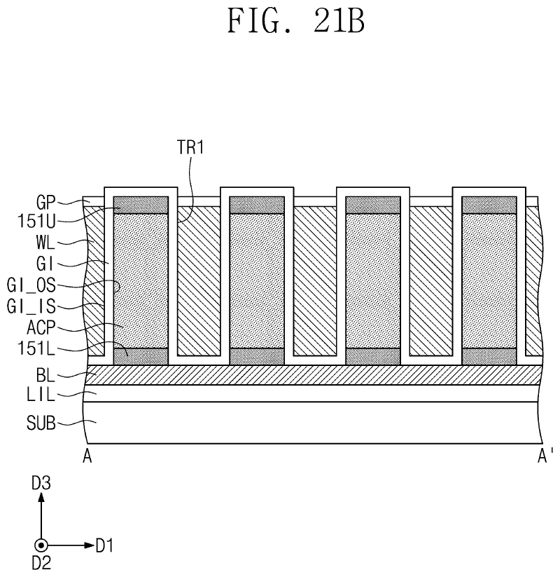

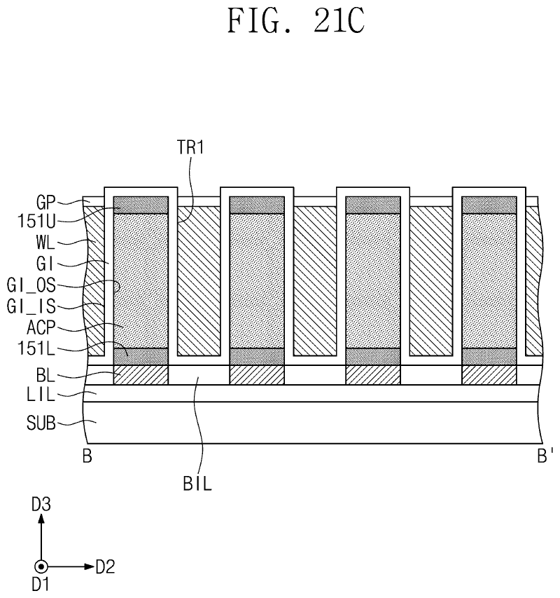

Referring to FIGS. 21A, 21B, and 21C, the word line WL may be formed on the gate insulating layer GI to cover the first recess RS1. A patterning process may be performed to form the word lines WL, which are extended lengthwise in the second direction D2 and are spaced apart from each other in the first direction D1. The word line WL may be formed on the first side surface GI_IS of the gate insulating layer GI. The second side surface GI_OS of the gate insulating layer GI, which is opposite to the first side surface GI_IS, may be in contact with the lower intervening structure 151L, the channel layer ACP, the upper intervening structure 151U.

The gate capping layer GP may be formed on the word lines WL. The gate capping layer GP may be formed to cover the top surfaces of the word lines WL. The bottom surface of the gate capping layer GP may be in contact with the top surfaces of the word lines WL, and the side surface of the gate capping layer GP may be in contact with the side surface of the gate insulating layer GI.

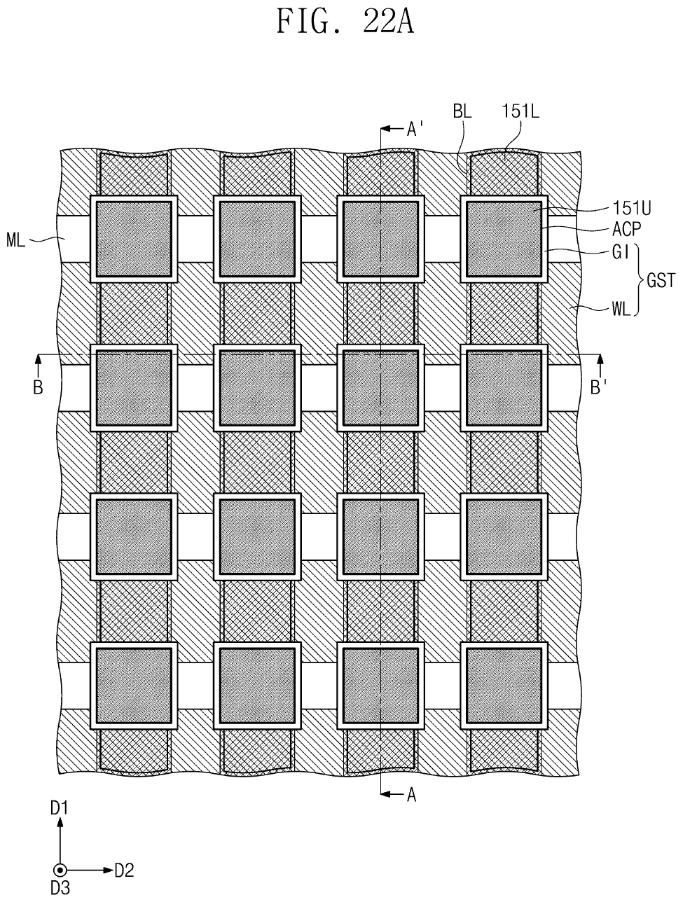

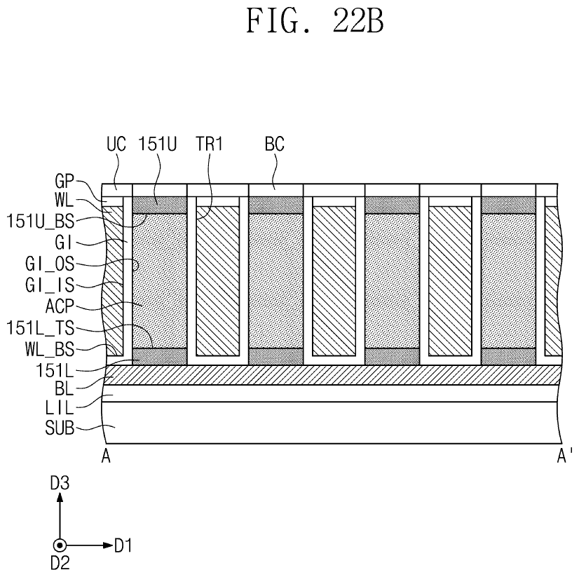

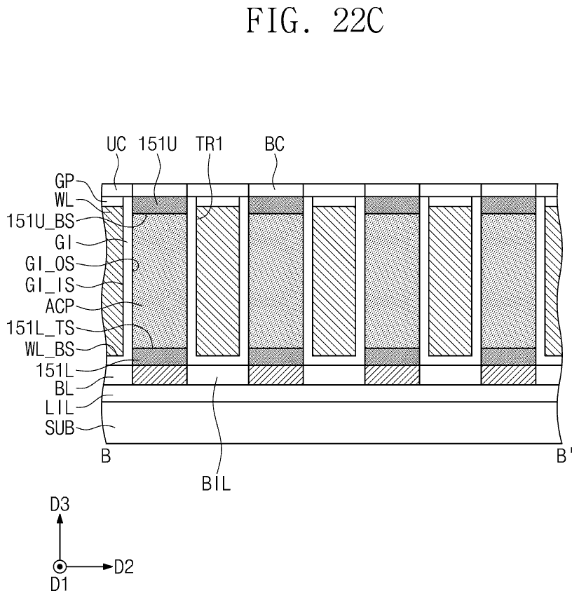

The mold layer ML may be formed between the word lines WL. In an embodiment, a plurality of mold layers ML may be formed. The mold layer ML may be formed between the gate insulating layers GI, which are adjacent to each other. Referring to FIGS. 22A, 22B, and 22C, a planarization process may be performed on the gate insulating layer GI and the gate capping pattern GP to remove a portion of the gate insulating layer GI, which is overlapped with the upper intervening structures 151U in the third direction D3, after the formation of the gate capping layer GP.

The planarization process on the gate insulating layer GI and the gate capping pattern GP may include exposing a top surface of the upper intervening structures 151U. As a result of the planarization process, the top surface of the gate insulating layer GI and the top surface of the gate capping pattern GP may be formed at substantially the same height.

The contact pattern BC may be formed on the exposed upper intervening structures 151U. The contact patterns BC may be formed to be spaced apart from each other in the first and second directions D1 and D2. The upper capping layer UC may be formed between the contact patterns BC, which are spaced apart from each other. The upper capping layer UC may be formed to cover the gate capping layer GP.

Referring back to FIGS. 7 and 8, the landing pads LP may be formed on the contact patterns BC, and the upper insulating layer UIL may be formed between the landing pads LP. The data storage pattern DSP may be formed on the landing pads LP. In this case, the semiconductor device may be formed to have the structure of FIGS. 7 and 8.

According to an embodiment of the inventive concept, a semiconductor device may include an intervening structure between a bit line and a channel layer. The intervening structure may include amorphous silicon. Thus, a contact resistance between the channel layer and a word line may be improved, and thermal stability of the semiconductor device may be improved.

According to an embodiment of the inventive concept, a semiconductor device may include a lower intervening structure between the bit line and the channel layer and an upper intervening structure between the channel layer and a landing pad. Thus, a contact resistance of the channel layer may be improved, and it may be possible to improve the thermal stability and electric characteristics of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a bit line extending lengthwise in a first direction;
a lower intervening structure on the bit line;
a channel layer in contact with the lower intervening structure and spaced apart from the bit line;
a word line extending lengthwise in a second direction crossing the first direction; and
a gate insulating layer between the channel layer and the word line,
wherein the lower intervening structure comprises amorphous silicon.

2. The semiconductor device of claim 1, further comprising a bit line insulating layer in contact with the bit line and the lower intervening structure.

3. The semiconductor device of claim 1,
wherein a top surface of the lower intervening structure is in contact with the channel layer, and
wherein a bottom surface of the lower intervening structure is in contact with the bit line.

4. The semiconductor device of claim 1, further comprising:
an upper intervening structure provided on the channel layer, and
a gate capping layer on the word line,
wherein the gate capping layer is not overlapped with the upper intervening structure.

5. The semiconductor device of claim 1, wherein the channel layer comprises at least one of IGZO, IGTO, ZnO, IZO, IZTO, or ZTO.

6. The semiconductor device of claim 1, wherein the lower intervening structure further comprises hydrogen.

7. The semiconductor device of claim 1, further comprising:
an upper intervening structure provided on the channel layer,
wherein the channel layer is located between the upper intervening structure and the lower intervening structure.

8. The semiconductor device of claim 7, further comprising:
a contact pattern on the channel layer; and
a landing pad connected to the contact pattern,
wherein the upper intervening structure comprises amorphous silicon.

9. The semiconductor device of claim 8, wherein the lower intervening structure, the landing pad, and the upper intervening structure are overlapped with each other in a third direction perpendicular to the first and second directions.

10. A semiconductor device, comprising:
a bit line extending lengthwise in a first direction;
a lower intervening structure on the bit line;
a channel layer in contact with the lower intervening structure;
a word line extending lengthwise in a second direction crossing the first direction; and
a gate insulating layer between the channel layer and the word line,
wherein the lower intervening structure comprises amorphous silicon, and
wherein the channel layer comprises an oxide material.

11. The semiconductor device of claim 10, further comprising:
a landing pad on the channel layer; and
a data storage pattern on the landing pad,
wherein the lower intervening structure, the landing pad, and the data storage pattern are overlapped with each other in a third direction perpendicular to the first and second directions.

12. The semiconductor device of claim 10, further comprising:
an upper intervening structure on the channel layer,
wherein the upper and lower intervening structures comprise hydrogen.

13. The semiconductor device of claim 12,
wherein a bottom surface of the upper intervening structure is spaced apart from the gate insulating layer, and
wherein the upper and lower intervening structures comprise the same material.

14. The semiconductor device of claim 10, wherein a top surface of the lower intervening structure is in contact with the gate insulating layer and the channel layer.

15. The semiconductor device of claim 10, wherein a distance from the bit line to a top surface of the lower intervening structure is smaller than a distance from the bit line to a bottom surface of the word line.

16. The semiconductor device of claim 10, wherein the gate insulating layer comprises:
a first side surface in contact with the word line, and
a second side surface, which is opposite to the first side surface of the gate insulating layer and is in contact with the channel layer and the lower intervening structure.

17. The semiconductor device of claim 16, further comprising:
an upper intervening structure on the channel layer,
wherein the second side surface of the gate insulating layer is in contact with the upper intervening structure.

18. A semiconductor device, comprising:
a bit line extending lengthwise in a first direction;
a lower intervening structure on the bit line;
a bit line insulating layer in contact with a side surface of the lower intervening structure and a side surface of the bit line;
a channel layer in contact with the lower intervening structure and spaced apart from the bit line;
a word line spaced apart from the channel layer in the first direction and extending lengthwise in a second direction crossing the first direction;
a gate insulating layer interposed between the channel layer and the word line;
a gate capping layer on the word line;
a landing pad on the channel layer; and
a data storage pattern connected to the landing pad,
wherein the lower intervening structure comprises amorphous silicon, and
wherein the channel layer comprises an oxide material.

19. The semiconductor device of claim 18, wherein the channel layer comprises at least one of IGZO, IGTO, ZnO, IZO, IZTO, or ZTO.

20. The semiconductor device of claim 18, further comprising:
an upper intervening structure between the channel layer and the landing pad,
wherein the upper intervening structure comprises amorphous silicon.
